(19) United States
(12) Patent Application Publication
(10) Pub. No.: US 2013/0029268 A1
(43) Pub. Date: Jan. 31, 2013

(54) PHOTOSENSITIVE PLANOGRAPHIC PRINTING PLATE PRECURSOR AND METHOD OF PRODUCING A PLANOGRAPHIC PRINTING PLATE

(71) Applicants: Ichiro KOYAMA, Shizuoka-ken (JP); Yoshinori TAGUCHI, Shizuoka-ken (JP)

(72) Inventors: Ichiro KOYAMA, Shizuoka-ken (JP); Yoshinori TAGUCHI, Shizuoka-ken (JP)

(73) Assignee: FUJIFILM CORPORATION, Tokyo (JP)

(21) Appl. No.: 13/535,362

(22) Filed: Jun. 28, 2012

(30) Foreign Application Priority Data
Jul. 25, 2011 (JP) 2011-162628

(51) Int. Cl. G03F 7/004; G03F 7/20

(52) U.S. Cl. 430/283.1; 430/270.1; 430/309

(57) ABSTRACT

The invention provides a planographic printing plate precursor that is capable of providing a planographic printing plate in which ablation at the time of infrared laser exposure is inhibited and which has excellent developability of a non-image portion and printing durability of an image portion. The photosensitive planographic printing plate precursor, includes: an image recording layer on a hydrophilic support, the image recording layer including: (A) an infrared absorber; and (B) a copolymer having a repeating unit having a zwitterionic structure in a side chain thereof, and a repeating unit having a heteroalicyclic structure or a repeating unit having a hetero atom and an alicyclic structure in the main chain thereof.

### CROSS-REFERENCE TO RELATED APPLICATION

This application claims priority under 35 USC 119 from Japanese Patent Application No. 2011-162628 filed on Jul. 25, 2011, the disclosure of which is incorporated by reference herein.

### BACKGROUND OF THE INVENTION

1. Field of the Invention

The present invention relates to a photosensitive planographic printing plate precursor and a method of producing a planographic printing plate.

2. Description of the Related Art

Techniques relating to laser exposure and development in image recording layers have undergone remarkable development. Particularly, a small sized high-power solid-state laser or semiconductor laser having a light-emitting region ranging from near infrared to infrared have been easily available. As an exposure light source used in directly recording an image from digital data of a computer or the like, a laser is very useful, and it is extremely important to develop an image recording layer adaptable to such lasers.

An image recording layer compatible to an infrared laser contains, as essential components, a binder resin and an IR dye that is excited and produces heat by absorbing infrared ray. The image recording layer compatible to an infrared laser has excellent stability and has excellent handleability since the image recording layer does not cause a concern of becoming photosensitive even under a white light. However, since a high-energy infrared laser is used for forming an image, undesirable ablation is caused in a local high-energy region in a photosensitive layer due to the heat produced by the IR dye, which leads to a concern that the laser instrument will be contaminated. If the ablation is generated, the laser instrument needs to be washed, which leads to a problem that the work efficiency deteriorates.

For the purpose of inhibiting ablation, means for improving coating properties of an image recording layer by using a binder that has a specific structure has been suggested (for example, see Japanese Patent Application Laid-Open (JP-A) No. 2008-197566).

In addition, means for inhibiting ablation by further providing a barrier layer on an image recording layer is known (for example, see JP-A No. 2003-156850).

Meanwhile, in order to improve film properties of an image recording layer, a technique has been suggested which uses an image recording layer containing an alkali-soluble vinyl polymer that has a ring structure in a main chain and has an active imide group as an alkali-soluble group (for example, see JP-A No. 2005-99631). It is mentioned that the abrasion resistance and chemical resistance of an image portion is improved according to this technique. Moreover, an image recording layer containing a polymer that has betaine in a side chain has been suggested (for example, see Japanese Unexamined Patent Publication (JP-T) No. 2008-509245), and it is known that using this composition makes it possible to form an image on a printing machine, for example.

### SUMMARY OF THE INVENTION

When an image recording layer containing a binder that is capable of improving film properties of the image recording layer is used, ablation is further inhibited, and printing durability is further improved. However, due to the high film properties, permeability of a developer in a non-image portion is suppressed, developability deteriorates, and affinity with the developer showing reduced activity deteriorates. Therefore, there is a concern that sufficient developability will not be obtained or that workability will deteriorate since it takes time for developing.

Moreover, when a barrier layer is further provided on an image recording layer, permeation of the developer into the image recording layer is delayed since the barrier layer has to be removed in advance in a development treatment, which leads to a problem in that the developability deteriorates.

When a specific binder as disclosed in JP-T No. 2008-509245 is used, the printing durability of an image portion is improved. However, the ablation at the time of exposure is not sufficiently inhibited. Accordingly, in the current circumstances, an image recording layer that is capable of inhibiting the ablation at the time of forming an image and realizing excellent printing durability and developability has not been found.

The present invention has been made in consideration of the above defects of the technique in the related art, and is to provide a planographic printing plate precursor that is capable of providing a planographic printing plate in which ablation at the time of infrared laser exposure is inhibited and excellent developability of a non-image portion is compatible with printing durability of an image portion. Furthermore, the present invention is to provide a method of producing a planographic printing plate by which a planographic printing plate excellent in both the durability (printing durability) and the developability is obtained.

The inventors of the present invention have conducted extensive studies, and as a result, they have found that the above objects are accomplished by using a photosensitive planographic printing plate precursor having, on a hydrophilic support, an image recording layer containing at least (A) an infrared absorber and (B) a copolymer that contains at least a repeating unit having a zwitterionic structure in a side chain, and a repeating unit having a heteroalicyclic structure in a main chain thereof or a repeating unit having a hetero atom and an alicyclic structure in a main chain thereof. In this manner, the inventors of the present invention have completed the present invention.

Examples of embodiments of the present invention will be described below.

<1> A photosensitive planographic printing plate precursor, comprising:

a hydrophilic support; and

an image recording layer on the hydrophilic support, the image recording layer comprising:
(A) an infrared absorber; and
(B) a copolymer comprising a repeating unit having a zwitterionic structure in a side chain thereof, and either a repeating unit having a heteroalicyclic structure in a main chain thereof or a repeating unit having a hetero atom and an alicyclic structure in a main chain thereof.

<2> The photosensitive planographic printing plate precursor according to <1>, wherein the heteroalicyclic structure is an acetal structure or a maleimide structure.

<3> The photosensitive planographic printing plate precursor according to <1> or <2>, wherein the repeating unit having a heteroalicyclic structure in a main chain thereof comprises a repeating unit represented by the following Formula (I) or (II):

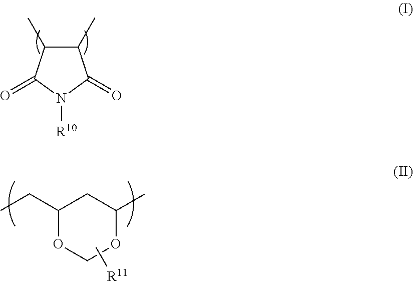

wherein, in Formula (I) and (II), each of R¹⁰ and R¹¹ independently represents a hydrogen atom or a monovalent organic group.

<4> The photosensitive planographic printing plate precursor according to <3>, wherein the monovalent organic group represented by R¹⁰ or R¹¹ is selected from the group consisting of an alkyl group having 1 to 8 carbon atoms, an aryl group having 6 to 10 carbon atoms, a hydroxyl group, and a SO₂NH₂ group.

<5> The photosensitive planographic printing plate precursor according to <1>, wherein the repeating unit having a hetero atom and an alicyclic structure in a main chain thereof comprises a repeating unit represented by the following Formula (IV):

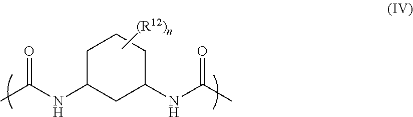

wherein, in Formula (IV), R¹² represents a hydrogen atom or a monovalent organic group; n represents an integer of 1 to 4; and when n represents an integer of 2 to 4, plural R¹²'s may be the same as or different from each other.

<6> The photosensitive planographic printing plate precursor according to <5>, wherein the monovalent organic group represented by R¹² is selected from the group consisting of an alkyl group having 1 to 8 carbon atoms, an aryl group having 6 to 10 carbon atoms, a hydroxyl group, and a SO₂NH₂ group.

<7> The photosensitive planographic printing plate precursor according to any one of <1> to <6>, wherein the zwitterionic structure is a sulfobetaine structure, a carboxybetaine structure, or a phosphobetaine structure.

<8> The photosensitive planographic printing plate precursor according to any one of <I> to <7>, wherein the (A) infrared absorber is a cyanine dye.

<9> The photosensitive planographic printing plate precursor according to any one of <1> to <8>, wherein the (B) copolymer further comprises a repeating unit having an alkali-soluble group.

<10> The photosensitive planographic printing plate precursor according to any one of <1> to <9>, wherein the image recording layer further comprises an alkali-soluble resin that is different from the (B) copolymer.

<11> The photosensitive planographic printing plate precursor according to <10>, which is a positive-working photosensitive planographic printing plate precursor.

<12> The photosensitive planographic printing plate precursor according to any one of <1> to <9>, wherein the image recording layer further comprises a polymerizable compound and a polymerization initiator, and the photosensitive planographic printing plate precursor is a negative-working photosensitive planographic printing plate precursor.

<13> A method of producing a planographic printing plate, comprising:

subjecting the photosensitive planographic printing plate precursor of any one of <1> to <12> to imagewise light exposure; and

developing the photosensitive planographic printing plate precursor after the imagewise light exposure.

According to the present invention, a planographic printing plate precursor is provided, which is capable of providing a planographic printing plate in which ablation at the time of infrared laser exposure is inhibited and excellent developability of a non-image portion is compatible with printing durability of an image portion. According to another aspect of the present invention, a method of producing a planographic printing plate is provided, which is capable of producing a planographic printing plate excellent in both the durability (printing durability) and the developability.

### BRIEF DESCRIPTION OF THE DRAWINGS

FIG. 1 is a cross-sectional view schematically showing an embodiment of the multilayer configuration of a planographic printing plate precursor of the present invention; and

FIG. 2 is a cross-sectional view schematically showing an embodiment of the single-layer configuration of a planographic printing plate precursor of the present invention.

### DETAILED DESCRIPTION OF THE INVENTION

Hereinbelow, the photosensitive planographic printing plate precursor and the method of producing a planographic printing plate of the present invention will be described in detail. The following description of the constituent elements is based on representative embodiments of the present invention, and the present invention is not limited to these embodiments.

In the present specification, a range of numerical values indicated using “to” means a range that includes numerical values before and after “to” as a lower limit and an upper limit, respectively.

The “alkyl group” as used in the present specification refers to a “linear, branched, or cyclic” alkyl group. In addition, the substituent (atomic group) in the present specification is used in a sense including an unsubstituted group and a group further having an additional substituent. For example, in the present specification, the term “alkyl group” refers to an unsubstituted or substituted alkyl group, and this is also applicable to other substituents in the same manner.

In the present specification, “(meth)acrylate” refers to either or both of acrylate and methacrylate, “(meth)acryl” refers to either or both of acryl and methacryl, and “(meth)acryloyl” refers to either or both of acryloyl and methacryloyl.

In the present specification, a “monomeric substance” has the same definition as a “monomer”. As used in the present specification, the “monomer” is distinguished from an oligomer and a polymer, and refers to a compound having a weight average molecular weight of 2,000 or less. In the present specification, a polymerizable compound refers to a compound having a polymerizable functional group and may be a monomer or a polymer. A polymerizable functional group refers to a group involved in a polymerization reaction.

In the present specification, a term “step” includes not only an independent step but also a step that is not clearly distinguished from other steps so long as the desired operation of this step is accomplished.

Photosensitive Planographic Printing Plate Precursor

The photosensitive planographic printing plate precursor of the present invention has at least: a hydrophilic support; and an image recording layer provided on the hydrophilic support, in which the image recording layer includes: (A) an infrared absorber; and (B) a copolymer that includes a repeating unit having a zwitterionic structure at a side chain thereof, and a repeating unit having a heteroalicyclic structure at a main chain thereof or a repeating unit having a hetero atom and an alicyclic structure at a main chain thereof.

Although it is not clear, the mechanism of the present invention is presumed to be as below.

In the photosensitive planographic printing plate precursor of the present invention, an image recording layer including (A) an infrared absorber and (B) a copolymer that includes a repeating unit having a zwitterionic structure in a side chain thereof, and a repeating unit having a heteroalicyclic structure in a main chain thereof or a repeating unit having a hetero atom and an alicyclic structure in a main chain thereof is provided on a hydrophilic support. Accordingly, since the infrared absorber as a low-molecular weight component that is easily scattered by local heating interacts with the copolymer having a zwitterionic structure, ablation is effectively inhibited. In addition, since the copolymer contained in the image recording layer has a bulky ring structure in a main chain thereof, the rigidity of a polymer is increased, and film properties are improved, whereby ablation is effectively inhibited even in an area in which heat is locally generated. Furthermore, since the zwitterionic structure that causes excellent solubility to be expressed by contacting excess alkaline developer is at the end of a side chain, the mobility of the zwitterionic structure becomes excellent, which is considered to cause excellent developability to be achieved. Consequently, presumably, it is possible to provide a planographic printing plate precursor that is capable of providing a planographic printing plate in which ablation at the time of infrared laser exposure is inhibited and the excellent developability in a non-image portion is compatible with the printing durability in an image portion.

Image Recording Layer

The image recording layer in the present invention contains at least: (A) an infrared absorber and (B) a copolymer that includes a repeating unit having a zwitterionic structure at a side chain thereof, and a repeating unit having a heteroalicyclic structure at a main chain thereof or a repeating unit having a hetero atom and an alicyclic structure at a main chain thereof. The image recording layer may optionally contain other components.

Hereinbelow, the respective components will be described.

### (A) Infrared Absorber

In the photosensitive planographic printing plate precursor of the present invention, the image recording layer thereof contains (A) an infrared absorber.

As the (A) infrared absorber, various dyes known as infrared absorbers may be used without particular limitation, as long as the dyes are capable of producing heat by absorbing infrared light.

As the infrared absorber usable for the image recording layer in the present invention, commercially available dyes and known infrared absorbers disclosed in documents (for example, “Handbook of Dyes” edited by The Society of Synthetic Organic Chemistry, Japan, 1970) may be used.

Specific examples thereof include dyes such as an azo dye, a metal complex salt azo dye, a pyrazoloazo dye, an anthraquinone dye, a phthalocyanine dye, an oxonol dye, a squarylium pigment, a pyrylium salt, a thiopyrylium dye, a nickel thiolate complex, a carbonium dye, a quinonimine dye, a methine dye, and a cyanine dye. Among these, examples of particularly preferable dyes include a cyanine pigment, a phthalocyanine dye, an oxonol dye, a squarylium pigment, a pyrylium salt, a thiopyrylium dye, and a nickel thiolate complex.

In the present invention, dyes that is capable of absorbing at least infrared light or near infrared light are preferable among the above dyes, in respect that such dyes are suitably used in combination with a laser emitting infrared light or near infrared light.

Examples of the dyes that is capable of absorbing at least infrared light or near infrared light include cyanine dyes as disclosed in JP-A No. 58-125246, JP-A No. 59-84356, JP-A No. 59-202829, JP-A No. 60-78787, and the like; methine dyes as disclosed in JP-A No. 58-173696, JP-A No. 58-181690, JP-A No. 58-194595, and the like; naphthoquinone dyes as disclosed in JP-A No. 58-112793, JP-A No. 58-224793, JP-A No. 59-48187, JP-A No. 59-73996, JP-A No. 60-52940, JP-A No. 60-63744, and the like; squarylium colorants as disclosed in JP-A No. 58-112792 and the like; and cyanine dyes disclosed in the specification of UK Patent No. 434,875.

As the dye, a near infrared-absorbing sensitizer disclosed in the specification of U.S. Pat. No. 5,156,938 is also preferably used. Examples of the dyes also include a substituted aryl benzo(thio)pyrylium salt disclosed in the specification of U.S. Pat. No. 3,881,924, a trimethine thiapyrylium salt disclosed in JP-A No. 57-142645 (specification of U.S. Pat. No. 4,327,169), pyrylium compounds disclosed in JP-A No. 58-181051, JP-A No. 58-220143, JP-A No. 59-41363, JP-A No. 59-84248, JP-A No. 59-84249, JP-A No. 59-146063, and JP-A No. 59-146061 respectively, cyanine pigments disclosed in JP-A-59-216146, a pentamethine thiopyrylium salt disclosed in the specification of US Pat. No. 4,283,475, and pyrylium compounds disclosed in Japanese Examined Patent Application Publication (JP-B) No. 5-13514 and JP-B-5 No. 19702.

As commercially available products, EPOLIGHT III-178, EPOLIGHT III-130, EPOLIGHT III-125, and the like (trade names, manufactured by Epolin Inc.) are particularly preferably used.

Other examples of the particularly preferable dyes include near infrared-absorbing dyes represented by Formulae (I) and (ID, which are disclosed in the specification of U.S. Pat. No. 4,756,993.

In the present specification, for example, when a compound is described as a “XX compound” such as a “pyrylium compound”, this means that the compound includes the salt and ions thereof in addition to the “XX compound” itself. For example, the term “pyrylium compound” in the present specification encompasses a pyrylium compound and salts and ions thereof. Typically, a “XX compound” refers to the XX compound and/or a salt thereof.

Among these dyes, a cyanine dye is particularly preferable from the viewpoint of absorbing infrared light or near infrared light.

Furthermore, a cyanine dye represented by the following Formula (a) is most preferably used because high polymerization activity is obtained and stability and economics become excellent when the cyanine dye is used in an upper layer in the invention.

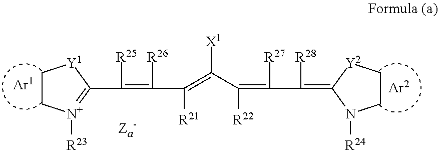

In Formula (a), X¹ represents a hydrogen atom, a halogen atom, —NPh₂, X²-L¹, or a group shown below.

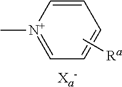

In the above formula, Xa⁻ has the same definition as Za⁻ described later, R^{a} represents a substituent selected from a group consisting of a hydrogen atom, an alkyl group, an aryl group, a substituted or unsubstituted amino group, and a halogen atom.

In Formula (a), X² represents an oxygen atom or a sulfur atom; and

L¹ represents a hydrocarbon group having 1 to 12 carbon atoms, an aromatic ring having a hetero atom, or a hydrocarbon group having 1 to 12 carbon atoms and containing a hetero atom. The hetero atom herein refers to N, S, O, a halogen atom, or Se.

In Formula (a), each of R²¹ and R²² independently represents a hydrocarbon group having 1 to 12 carbon atoms. In view of the storage stability of a coating liquid for a photosensitive layer, R²¹ and R²² are each preferably a hydrocarbon group having 2 or more carbon atoms, and it is particularly preferable that R²¹ and R²² are bonded to each other to form a 5- or 6-membered ring.

In Formula (a), Ar¹ and Ar² may be the same as or different from each other, and each independently represent a substituted or unsubstituted aromatic hydrocarbon group. Examples of preferable aromatic hydrocarbon groups include a benzene ring and a naphthalene ring. Examples of preferable substituents include a hydrocarbon group having 12 or less carbon atoms, a halogen atom, and an alkoxy group having 12 or less carbon atoms.

In Formula (a), Y¹ and Y² may be the same as or different from each other, and each independently represent a sulfur atom or a dialkyl methylene group having 12 or less carbon atoms.

In Formula (a), R²³ and R²⁴ may be the same as or different from each other, and each independently represent a hydrocarbon group which has 20 or less carbon atoms and which may have a substituent. Examples of preferable substituents include an alkoxy group having 12 or less carbon atoms, a carboxyl group, and a sulfo group.

In Formula (a), R²⁵, R²⁶, R²⁷, and R²⁸ may be the same as or different from each other, and each independently represent a hydrogen atom or a hydrocarbon group having 12 or less carbon atoms. A hydrogen atom is preferable in terms of the availability of the material.

In Formula (a), Za⁻ represents a counter anion. Here, when the cyanine pigment represented by Formula (a) has an anionic substituent in the structure thereof, and the charge does not need to be neutralized, Za⁻ is unnecessary. From the viewpoint of the storage stability of a coating liquid for a photosensitive layer, Za⁻ is preferably a halogen ion, a perchloric acid anion, a tetrafluoroborate ion, a hexafluorophosphate ion, or a sulfonic acid ion, and particularly preferably a perchloric acid ion, a hexafluorophosphate ion, or an arylsulfonic acid ion.

Specific examples of the cyanine pigment represented by Formula (a) that may be preferably used in the invention include dyes disclosed in Paragraphs [0017] to [0019] of JP-A No. 2001-133969, Paragraphs [0012] to [0038] of JP-A No. 2002-40638, and Paragraphs [0012] to [0023] of JP-A No. 2002-23360.

Examples of particularly preferable infrared absorbers include a cyanine dye A and IR-1 shown below, and among these, the cyanine dye A is most preferable.

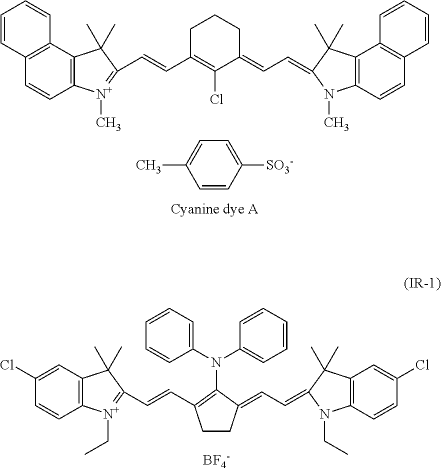

The image recording layer according to the present invention contains at least one type of the (A) infrared absorber, and may optionally include 2 or more types of the infrared absorbers.

The content of the (A) infrared absorber (or the total content when 2 or more types of (A) infrared absorber are used) is preferably from 0.01% by mass to 50% by mass, more preferably from 0.1% by mass to 30% by mass, and particularly preferably from 1.0% by mass to 30% by mass, based on the total solid content of the image recording layer.

When the content is 0.01% by mass or more, sensitivity of the image recording layer is increased. When the content is 50% by mass or less, the uniformity and the durability of the layer are excellent.

In the present specification, the total solid content of the image recording layer refers to the total content of the respective components of the image recording layer, other than a solvent.

### (B) Copolymer

The image recording layer of the photosensitive planographic printing plate precursor of the present invention contains (B) a copolymer that has at least: a repeating unit having a zwitterionic structure in a side chain thereof; and a repeating unit having a heteroalicyclic structure on a main chain thereof or a repeating unit having a hetero atom and an alicyclic structure on a main chain thereof (hereinbelow, may be referred to as a “repeating unit having a ring structure on a main chain” in general). The (B) copolymer may optionally contain other repeating units.

Repeating Unit Having Zwitterionic Structure on Side Chain

The repeating unit having a zwitterionic structure at a side chain, which is contained in the photosensitive planographic printing plate precursor of the present invention, is not particularly limited so long as the repeating unit capable of interacting with the infrared absorber or with the binder by electrostatic interaction.

The zwitterionic structure in the repeating unit having a zwitterionic structure in a side chain is present as a side chain of the (B) copolymer.

The zwitterionic structure is preferably sulfobetaine, carboxybetaine, or phosphobetaine, more preferably sulfobetaine or carboxybetaine, and particularly preferably sulfobetaine.

In the zwitterionic structure present in a side chain of the (B) copolymer, it is preferable that an anionic atom and a cationic atom that are present at the end of a side chain or near the end of a side chain be separated from each other at a distance of 1 to 10 atoms, since the anionic property and the cationic property of the atoms are enhanced, and a superior ablation inhibiting effect and developability may be obtained in proportion to the amount of the zwitterionic structure introduced. An embodiment is more preferable in which an anionic atom and a cationic atom are separated from each other at a distance of 2 to 4 atoms.

Specific examples of the repeating unit having a zwitterionic structure in a side chain thereof, which is used in the present invention, are shown below, but the present invention is not limited thereto.

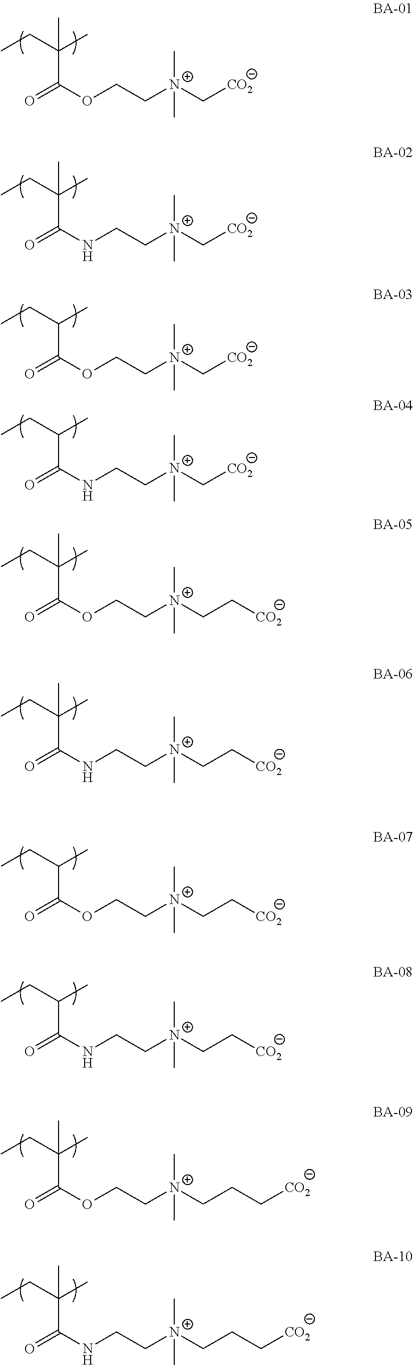

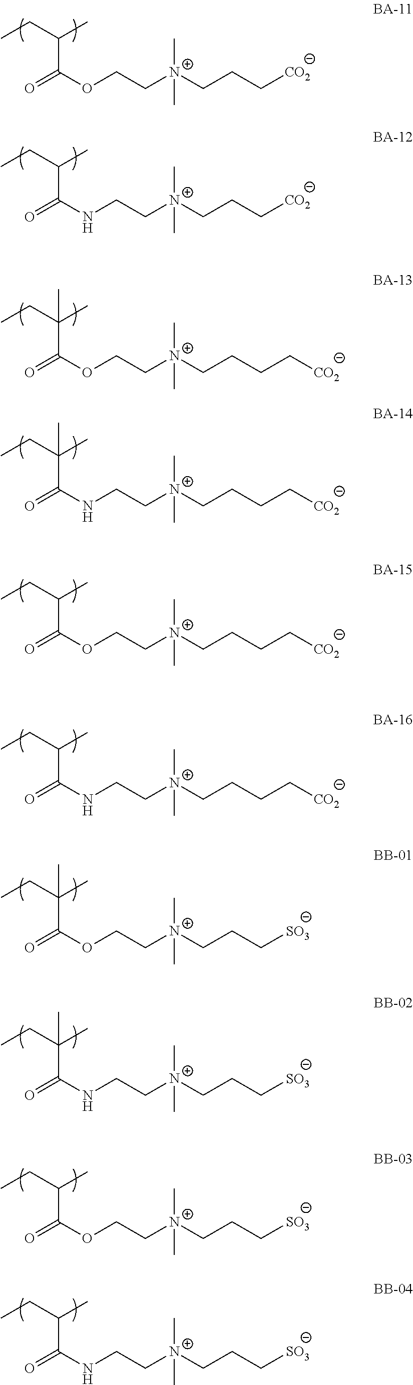

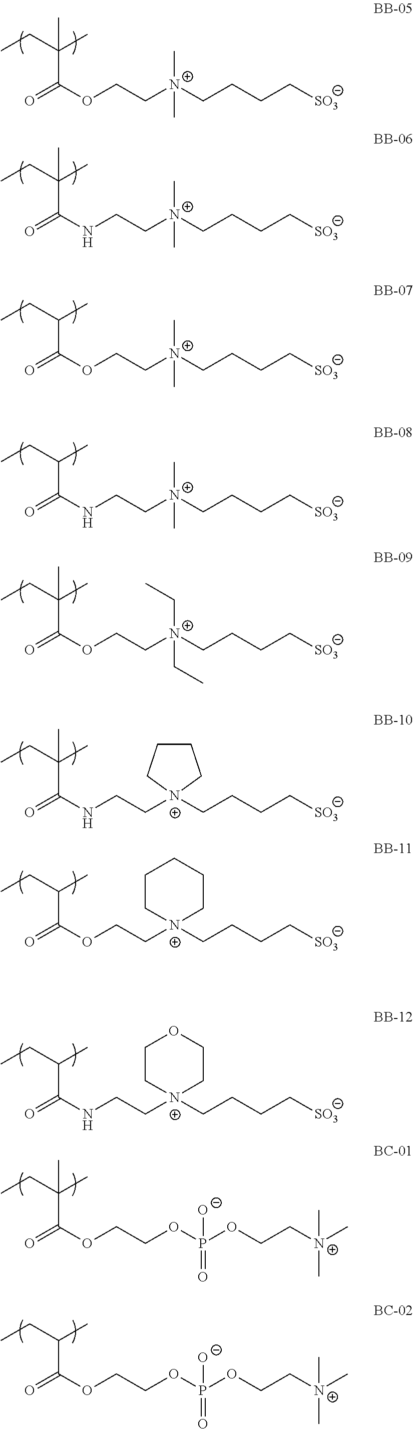

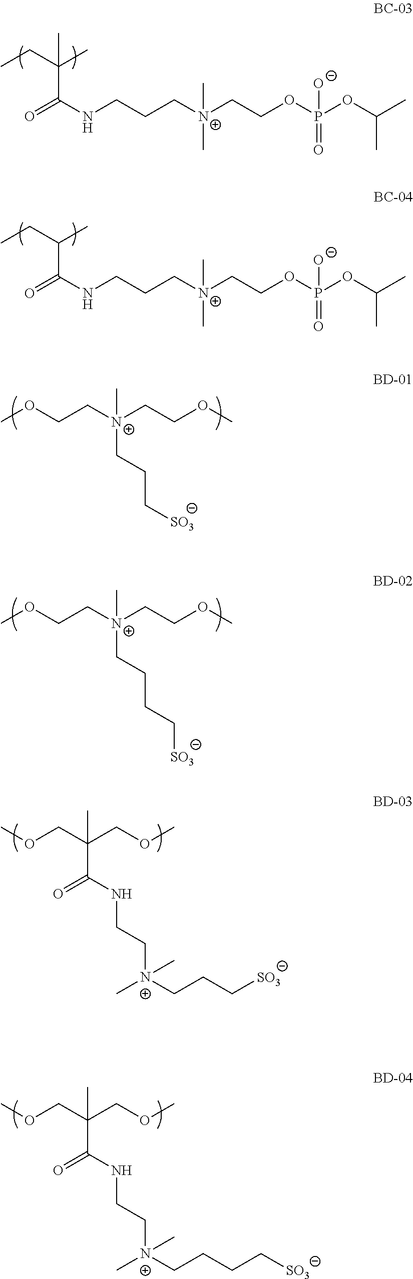

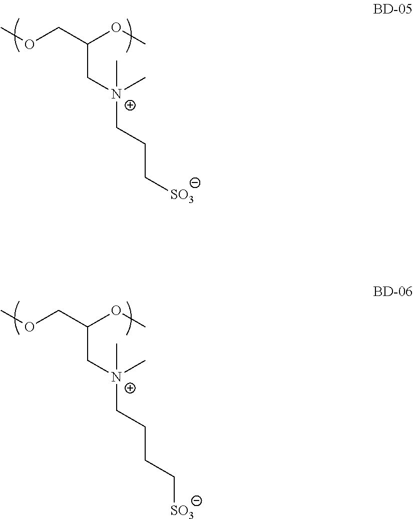

Among the specific examples of the repeating unit having a zwitterionic structure on a side chain, BA-05 to BA-16, BB-01 to BB-12, BD-01, BD-02, BD-05, and BD-06 are preferable, and BB-06, BB-08, BD-01, and BD-02 are more preferable, from the viewpoints of synthesis suitability and the distance between a cationic atom and an anionic atom.

The specific examples of the repeating unit having a zwitterionic structure in a side chain may be synthesized by any known method. Terminal groups in the repeating unit may also be synthesized by any known method. The synthesis may be conducted according to any known method such as the method disclosed in Journal of Organic Chemistry, 1969, vol. 34, p. 4065-4070.

It is necessary that the (B) copolymer according to the present invention have at least one type of the repeating unit having a zwitterionic structure in a side chain thereof. The (B) copolymer may contain two or more types of the repeating units having a zwitterionic structure on a side chain thereof.

The copolymerization ratio of the repeating unit(s) having a zwitterionic structure on a side chain thereof, in the (B) copolymer is preferably from 5 mol % to 95 mol %, more preferably from 5 mol % to 85 mol %, and particularly preferably from 5 mol % to 80 mol %.

Repeating Unit Having Ring Structure in Main Chain

In the present specification, the recitation “having a ring structure in a main chain” or the like means that some of the atoms constituting a main chain of the (B) copolymer forms a portion of a ring structure. Such a ring structure may be used without limitation, as long as the rigidity of a polymer is improved due to the ring structure included, and the strength of a film (recording layer) to be formed is enhanced.

That is, the ring structure of the repeating unit having a ring structure in a main chain serves as at least a part of the main chain of the (B) copolymer.

The ring structure present in the repeating unit according to the present invention is arbitrarily selected from 4- to 9-membered rings in consideration of the synthesis suitability or the like. In particular, the ring structure is preferably a 4- to 6-membered ring, and particularly preferably a 5- or 6-membered ring, from the viewpoint of the rigidity of the polymer.

It is preferable that the ring structure have a hetero atom as an atom constituting the ring structure since the rigidity improvement and the film strength improvement caused by the increase in polarity may be expected. There is no particular limitation on the hetero atom that may be contained in the ring structure, but examples of preferable hetero atoms include an oxygen atom, a nitrogen atom, and a sulfur atom. Examples of more preferable hetero atoms include an oxygen atom and a nitrogen atom.

Examples of the heteroaliphatic ring structure include an acetal structure and a maleimide structure.

Examples of the preferable repeating unit having a heteroalicyclic structure in a main chain include repeating units represented by the following Formulae (I) and (II), respectively.

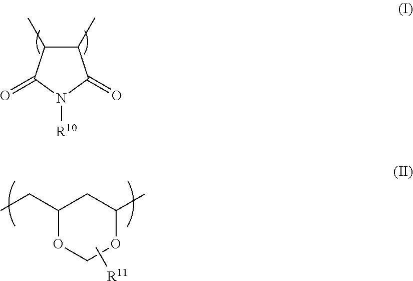

In Formulae (I) and (II), each of R¹⁰ and R¹¹ independently represents a hydrogen atom or a monovalent organic group.

Examples of the monovalent organic group include an alkyl group, an aryl group, a hydroxyl group, and a SO₂NH₂ group, and among these, an alkyl group and an aryl group are preferable.

The alkyl group or the aryl group may be substituted with an arbitrary substituent.

Examples of the alkyl group include a linear or branched alkyl group having 1 to 8 carbon atoms, and examples of preferable alkyl groups include a methyl group, an ethyl group, an isopropyl group, an n-propyl group, an n-butyl group, an iso-butyl group, a tert-butyl group, a hexyl group, and a 2-ethylhexyl group. Among these, a methyl group, an ethyl group, and an n-propyl group are more preferable, and an n-propyl group is particularly preferable.

Examples of the aryl group include a monocyclic or ring-condensed aryl group having 6 to 10 carbon atoms. In particular, a phenyl group is preferable.

Examples of the substituent which may be introduced to the alkyl group or aryl group represented by R¹⁰ or R¹¹ include a monovalent substituent having an alkyl group (for example, a methyl group, an ethyl group, or an n-propyl group), an alkoxy group (for example, a methoxy group, an ethoxy group, or an n-propyloxy group), a hydroxyl group, a halogen atom (for example, a fluorine atom, a chlorine atom, or a bromine atom), a cyano group, a nitro group, a carboxyl group, or an aminosulfonyl group; and a monovalent organic group having an active imide group (examples thereof including —SO₂NHCOR, —SO₂NHSO₂R, and —CONHSO₂R).

In Formula (I), R¹⁰ preferably represents a propyl group or a phenyl group, and more preferably represents a phenyl group.

In Formula (II), R¹¹ preferably represents an ethyl group or a propyl group, and more preferably represents a propyl group.

Examples of the preferable repeating unit having a hetero atom and an alicyclic structure on a main chain include a repeating unit represented by the following Formula (IV).

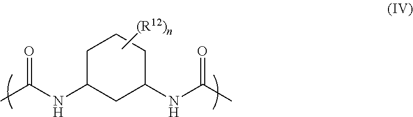

In Formula (IV), R¹² represents a hydrogen atom or a monovalent organic group; n represents an integer of from 1 to 4; and when n is an integer of from 2 to 4, plural R¹²'s may be the same as or different from each other.

Examples of the monovalent organic group represented by R¹² include an alkyl group, an aryl group, a hydroxyl group, and a SO₂NH₂ group, and among these, an alkyl group and an aryl group are preferable.

The alkyl group and the aryl group represented by R¹² have the same definitions as those of the alkyl group and aryl group which are examples of the monovalent organic group represented by R¹⁰ or R¹¹ in Formula (I) or (II).

In Formula (IV), n preferably represents an integer of from 0 to 2, and more preferably represents an integer of from 0 to 1.

Specific examples of the repeating unit having a ring structure on a main chain, which is used in the present invention, are shown below, but the present invention is not limited thereto.

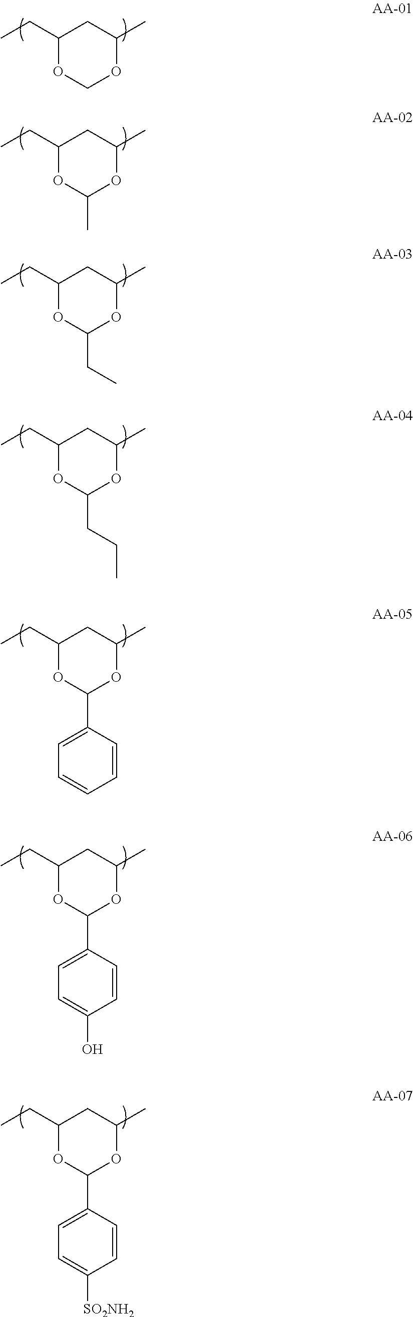

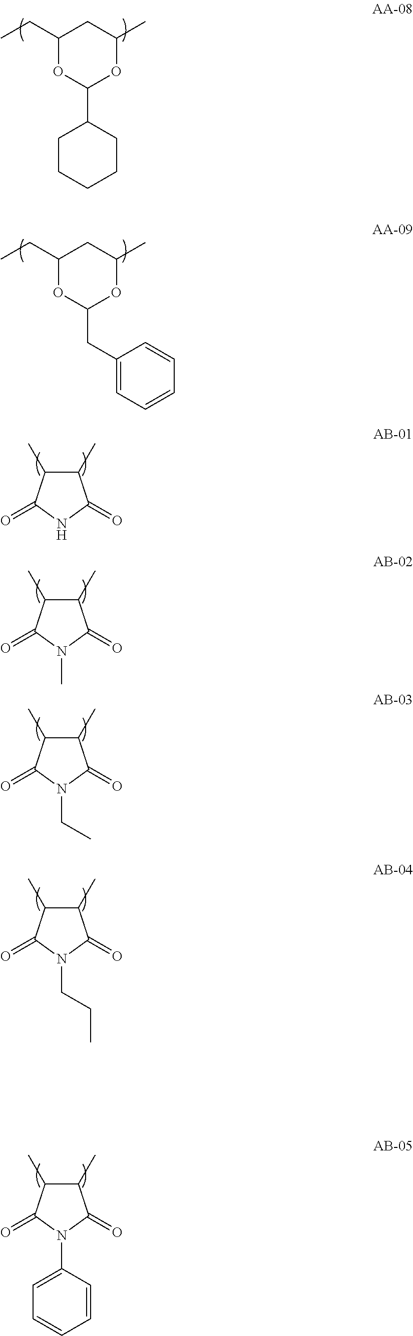

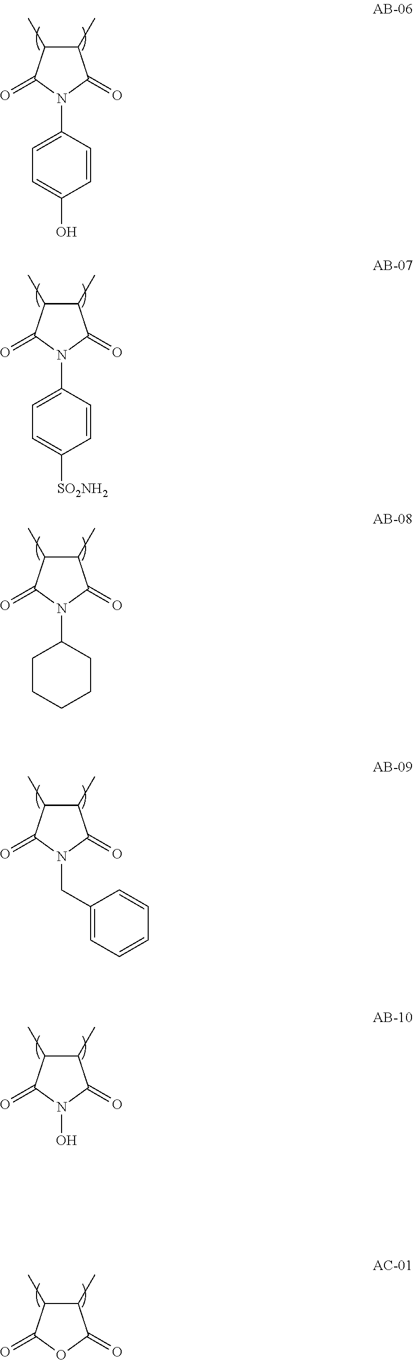

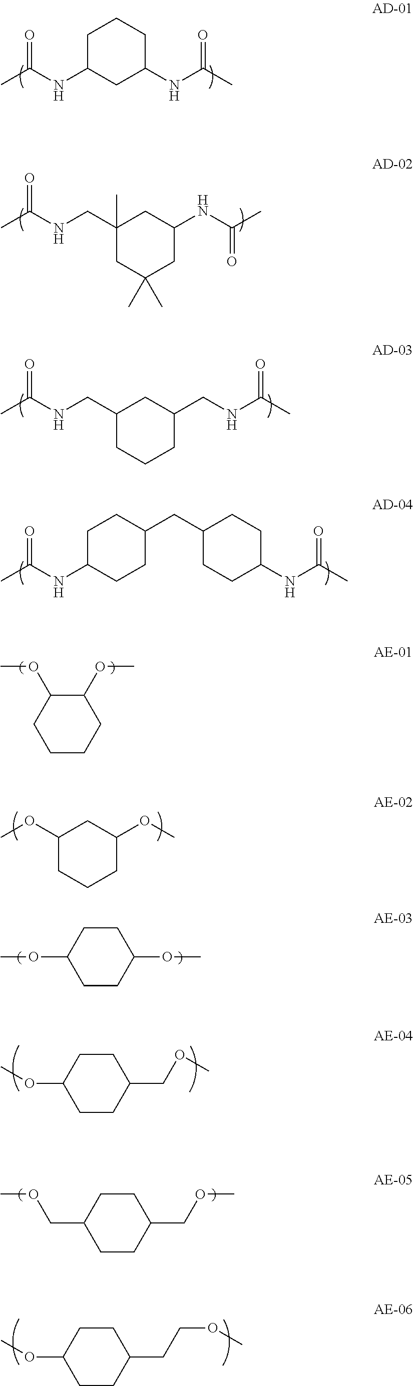

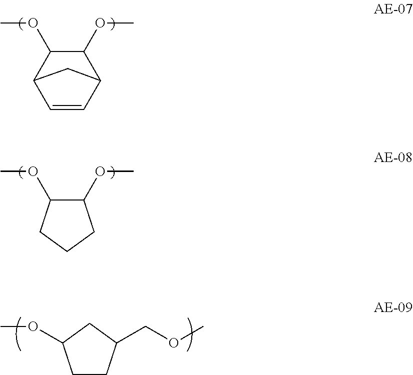

Among the specific examples of the repeating unit having a ring structure on a main chain, AA-02 to AA-08 and AD-01 to AD-04 are preferable, and AA-04 and AD-02 are more preferable, from the viewpoints of the synthesis suitability and the stability.

The specific examples of the repeating unit having a ring structure on a main chain can be synthesized by any known method. In addition, terminal groups in the repeating unit may also be synthesized by any known method. The synthesis may be conducted according to any known method such as a method disclosed in “Experimental Chemistry Course” (MARUZEN Co, Ltd, fifth edition, vol. 16).

It is necessary that the (B) copolymer according to the present invention contain at least one type of the repeating unit having a ring structure on a main chain, and may contain two or more types of the repeating unit having a ring structure on a main chain.

The copolymerization ratio of the repeating unit(s) having a ring structure on a main chain, in the (B)copolymer, is preferably from 10 mol % to 80 mol %, more preferably from 15 mol % to 60 mol %, and particularly preferably from 20 mol % to 50 mol %.

It is preferable that the (B) copolymer is a copolymer containing: at least one repeating unit selected from the group consisting of BA-05 to BA-16, BB-01 to BB-12, BD-01, BD-02, BD-05, and BD-06 as the repeating unit having a zwitterionic structure on a side chain; and at least one repeating unit selected from the group consisting of AA-02 to AA-08 and AD-01 to AD-04 as the repeating unit having a ring structure on a main chain.

It is more preferable that the (B) copolymer is a copolymer containing: at least one repeating unit selected from the group consisting of BB-06, BB-08, BD-01, and BD-02 as the repeating unit having a zwitterionic structure on a side chain thereof; and at least one repeating unit selected from the group consisting of AA-04 and AD-02 as the repeating unit having a ring structure on a main chain thereof.

It is still more preferable that the (B) copolymer is a copolymer containing: BB-06 as the repeating unit having a zwitterionic structure on a side chain thereof; and AA-04 as the repeating unit having a ring structure on a main chain thereof.

Other Repeating Units

In a case in which a polymer chain of the (B) copolymer contained in the photosensitive planographic printing plate precursor of the present invention is synthesized by radical polymerization, the (B) copolymer may further contain a repeating unit having an alkali-soluble group, in addition to the repeating unit having a zwitterionic structure in a side chain and the repeating unit having a ring structure on a main chain, from the viewpoint of improving developability in an alkaline developer. Examples of the repeating unit having an alkali-soluble group include a polymerization unit of (meth)acrylic acid alkyl ester or (meth)acrylic acid aralkyl ester, a polymerization unit of (meth)acrylamide or a derivative thereof, a polymerization unit of α-hydroxymethyl acrylate, a styrene derivative, a polymerized unit of (meth)acrylonitrile, and the like.

Examples of the alkyl group of the (meth)acrylic acid alkyl ester include an alkyl group having 1 to 5 carbon atoms, and in particular, a methyl group, an ethyl group, an n-butyl group, an isobutyl group, and a tert-butyl group are preferable.

Examples of the (meth)acrylic acid aralkyl ester include benzyl (meth)acrylate. Examples of the (meth)acrylamide derivative include N-isopropylacrylamide, N-phenylmethacrylamide, N-(4-methoxycarbonylphenyl)methacrylamide, N,N-dimethylacrylamide, and morpholinoacrylamide. Examples of the α-hydroxymethyl acrylate include ethyl α-hydroxymethyl acrylate and cyclohexyl α-hydroxymethyl acrylate. Examples of the styrene derivative include styrene and 4-tert-butyl styrene.

In a case in which a polymer chain of the (B) copolymer used for the image recording layer of the present invention is synthesized by addition polymerization, the (B) copolymer may contain a polymerization unit of a diisocyanate compound, a diol compound, or the like, in addition to the repeating unit having a zwitterionic structure on a side chain and the repeating unit having a ring structure on a main chain.

Examples of the diisocyanate compound include a diisocyanate compound represented by the following Formula (1).

OCN-L¹-NCO Formula (1)

In Formula (1), L¹ represents a divalent aliphatic hydrocarbon group that may have a substituent or a divalent aromatic hydrocarbon group that may have a substituent. L¹ may optionally include other functional groups which is unreactive with an isocyanate group, for example, an ester group, a urethane group, an amide group, or a ureido group.

Examples of the diisocyanate compound represented by the Formula (1) specifically include:

aromatic diisocyanate compounds such as 2,4-tolylene diisocyanate, a dimer of 2,4-tolylene diisocyanate, 2,6-tolylenedilene diisocyanate, p-xylylene diisocyanate, m-xylylene diisocyanate, 4,4′-diphenylmethane diisocyanate, 1,5-naphthylene diisocyanate, or 3,3′-dimethylbiphenyl-4,4′-diisocyanate; aliphatic diisocyanate compounds such as hexamethylene diisocyanate, trimethyl hexamethylene diisocyanate, lysine diisocyanate, or dimer acid diisocyanate; and diisocyanate compounds as reaction products of a diol and a diisocyanate, such as an adduct obtained from 1 mol of 1,3-butylene glycol and 2 mol of tolylene diisocyanate.

These may be used alone, or in combination of two or more thereof.

The diol compound is not particularly limited and may be appropriately selected according to the purpose. Examples thereof include a polyether diol compound, a polyester diol compound, a polycarbonate diol compound, and the like. For example, diol compounds disclosed in Paragraphs [0016] to [0073] of JP-A No. 2001-312062 can be used.

Specific examples of the additional repeating units of the (B) copolymer optionally used in the present invention are shown below, but the present invention is not limited thereto.

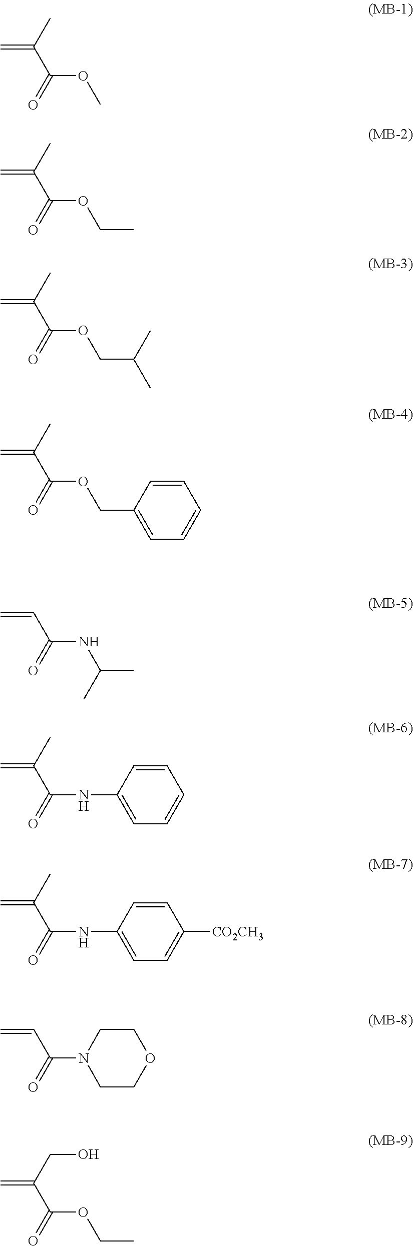

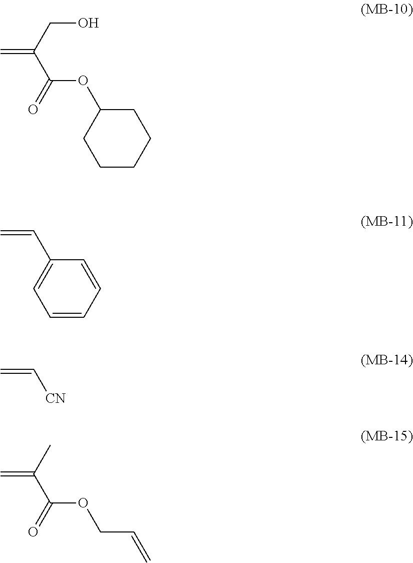

In addition to these structures, specific examples of the additional repeating units that may be contained in the (B) copolymer include ethylene glycol, propylene glycol, neopentyl glycol, 1,3-butylene glycol, 1,6-hexanediol, 2-butene-1,4-diol, 2,2,4-trimethyl-1,3-pentanediol, 1,4-bis-β-hydroxyethoxycyclohexane, cyclohexanedimethanol, tricyclodecanedimethanol, hydrogenated bisphenol A, hydrogenated bisphenol F, an ethylene oxide adduct of bisphenol A, a propylene oxide adduct of bisphenol A, an ethylene oxide adduct of bisphenol F, a propylene oxide adduct of bisphenol F, an ethylene oxide adduct of hydrogenated bisphenol A, a propylene oxide adduct of hydrogenated bisphenol A, hydroquinone dihydroxyethyl ether, p-xylylene glycol, dihydroxyethyl sulfone, bis-(2-hydroxyethyl)-2,4-tolylene dicarbamate, 2,4-tolylene-bis-(2-hydroxyethyl carbamide), bis-(2-hydroxyethyl)-m-xylylene carbamate, and bis-(2-hydroxyethyl)phthalate.

Among these structures, structures of (MB-1), (MB-2), (MB-3), (MB-11), (MB-12), (MB-13), and (MB-14) are particularly preferable from the viewpoint of printing durability, and structures of (MB-11), (MB-12), (MB-13), and (MB-14) are most preferable.

It is also preferable to concurrently use the following repeating units in addition to the above-mentioned structures, from the viewpoint of developability. Particularly preferable examples of such repeating units include ethylene glycol, propylene glycol, neopentyl glycol, 1,3-butylene glycol, 1,6-hexanediol, 2-butene-1,4-diol, and 2,2,4-trimethyl-1,3-pentanediol. As a repeating unit used for improving developability, ethylene glycol and propylene glycol are most preferable.

The (B) copolymer according to the present invention may contain one or two or more types of the additional repeating units described above.

The copolymerization ratio of the additional repeating unit(s) in the (B) copolymer is preferably from 0 mol % to 50 mol %, more preferably from 5 mol % to 40 mol %, and particularly preferably from 5 mol % to 30 mol %.

The mass average molecular weight of the (B) copolymer used in the present invention is preferably from 5,000 to 500,000, more preferably 10,000 to 250,000, even more preferably from 25,000 to 100,000, and still more preferably from 25,000 to 50,000.

In the present invention, a “molecular weight” refers to a mass average molecular weight unless otherwise specified. In addition, a molecular weight and dispersity refer to values measured by the following methods.

### Method of Measuring Molecular Weight and Dispersity

A molecular weight and dispersity are measured using a GPC (gel permeation chromatography) method unless otherwise specified. As the gel filled in a column used for the GPC method, a gel having an aromatic compound in a repeating unit is preferable, and examples thereof includes a gel formed from a styrene-divinyl benzene copolymer. Preferably, 2 to 6 columns are connected to each other for use.

Examples of solvents to be used include an ether solvent such as tetrahydrofuran and an amide solvent such as N-methylpyrrolidinone.

The measurement is performed preferably at a solvent flow rate in a range of from 0.1 mL/min to 2 mL/min, and most preferably at a solvent flow rate in a range of from 0.5 mL/min to 1.5 mL/min. When the measurement is performed with a solvent flow rate in the above ranges, the measurement is performed more efficiently without imposing a load onto the device.

The measurement is performed preferably at a temperature of from 10° C. to 50° C., and most preferably at a temperature of from 20° C. to 40° C.

The column and carrier to be used may be appropriately selected according to properties of a polymer compound to be measured.

The content of the (B) copolymer in the image recording layer is preferably from 5% by mass to 90% by mass, and more preferably from 10% by mass to 70% by mass, based on the total amount of the solid components (solid contents). When the content is equal to or less than the upper limit of the above ranges, development latitude becomes excellent, and when the content is equal to or more than the lower limit of the above ranges, printing durability becomes excellent.

The image recording layer of the photosensitive planographic printing plate precursor of the invention may be positive-working or negative-working. When the image recording layer is a positive-working image recording layer, the image recording layer may have a multilayer structure or a single layer structure.

Hereinbelow, various components contained in the image recording layer will be described respectively in a case of preparing a positive-working image recording layer (multilayer structure and a single layer structure) and in a case of preparing a negative-working image recording layer. Here, the present invention is not necessarily limited to the following description, and the positive-working and negative-working image recording layers may optionally contain the following various components in the respective layers appropriately.

Respective Components Contained in Lower Layer of Positive-Working Image Recording Layer Having Multilayer Structure

In a case of a positive-working multilayer structure, the infrared absorber is preferably contained in a lower layer. The lower layer may further contain other desired components as long as the components do not impair the effects of the present invention.

Examples of other components include alkali-soluble resins having a structure different from that of the (B) copolymer (hereinbelow, also referred to as “additional alkali-soluble resin”).

Additional Alkali-Soluble Resin

In the present invention, the term “alkali-soluble” means that a resin is soluble in an aqueous alkali solution of pH 8.5 to pH 13.5 by being treated for a standard developing time.

The alkali-soluble resin that has a structure different from that of the (B) copolymer and is used in the lower layer is not particularly limited, as long as the resin is capable of being dissolved in an alkaline developer. The alkali-soluble resin preferably has an acidic functional group such as a phenolic hydroxyl group, a sulfonic acid group, a phosphoric acid group, a sulfonamide group, or an active imide group on a main chain and/or a side chain in the polymer. Examples of the alkali-soluble resin include resins containing 10 mol % or more, more preferably 20 mol % or more, of monomers having such an acidic functional group imparting alkali-solubility. When the copolymerization ratio of the monomer capable of imparting alkali-solubility is 10 mol % or more, the alkali-solubility is sufficiently obtained, and the developability becomes excellent.

Examples of additional alkali-soluble resin also include condensation polymers of phenol and formaldehyde having an alkyl group having 3 to 8 carbon atoms as a substituent, such as a t-butylphenol formaldehyde resin or an octylphenol formaldehyde resin as disclosed in the specification of U.S. Pat. No. 4,123,279.

The mass average molecular weight (Mw) of the additional alkali-soluble resin is preferably 500 or more, and more preferably from 1,000 to 700,000. In addition, the number average molecular weight (Mn) thereof is preferably 500 or more, and more preferably from 750 to 650,000. The dispersity (mass average molecular weight/number average molecular weight) thereof is preferably from 1.1 to 10.

The additional alkali-soluble resin preferably has a mass average molecular weight of 2,000 or more and a number average molecular weight of 500 or more, and more preferably has a mass molecular weight of from 5,000 to 300,000 and a number average molecular weight of from 800 to 250,000. In addition, the dispersity (mass average molecular weight/number average molecular weight) of the additional alkali-soluble resin is preferably from 1.1 to 10.

The additional alkali-soluble resin optionally contained in the lower layer may be used alone, or in combination of two or more types thereof.

In the present invention, the amount of the additional alkali-soluble resin to be added may be from 0% by mass to 98% by mass, based on the total solid content of the lower layer. Moreover, the lower layer may contain the additional alkali-soluble resin in a proportion of 80 parts by mass or less with respect to 100 parts by mass of the (B) copolymer.

Respective Components Contained in Upper Layer of Positive-Working Image Recording Layer Having Multilayer Structure

In the upper layer of a positive-working image recording layer having a multilayer structure, a mechanism of improving solubility of the layer in an aqueous alkali solution caused by the heat in the upper layer is employed without particular limitation, and any mechanism may be used as long as the upper layer contains a binder resin and the solubility of the heated area is improved. Examples of heat used for forming an image include heat produced when the lower layer containing the infrared absorber is exposed to light.

The upper layer of which solubility in an aqueous alkali solution is improved by heat may be a layer containing an alkali-soluble resin capable of being bonded to hydrogen, such as novolac or urethane resin, a layer containing a water-insoluble but alkali-soluble resin and a compound showing a dissolution inhibiting action, a layer containing an ablative compound, or the like.

In addition, when the upper layer further contains an infrared absorber, the heat generated in the upper layer may also be utilized for forming an image. Examples of the configuration of the upper layer containing an infrared absorber include a layer containing an infrared absorber, a water-insoluble but alkali-soluble resin, and a compound showing a dissolution inhibiting action, a layer containing an infrared absorber, a water-insoluble but alkali-soluble resin, and a compound producing an acid by heat, and the like.

Hereinbelow, components contained in the upper layer will be described.

### Water-Insoluble but Alkali-Soluble Resin

The upper layer according to the present invention preferably contains a water-insoluble but alkali-soluble resin. When the upper layer contains a water-insoluble but alkali-soluble resin, the infrared absorber interacts with a polar group of the water-insoluble but alkali-soluble resin, whereby a positive-working photosensitive layer is formed. Examples of preferable water-insoluble but alkali-soluble resin include a polyamide resin, an epoxy resin, a polyacetal resin, an acrylic resin, a methacrylic resin, a polystyrene resin, and a phenol novolac resin.

The water-insoluble but alkali-soluble resin usable in the present invention is not particularly limited, as long as the resin has a characteristic of being dissolved when contacting an alkaline developer. However, the water-insoluble but alkali-soluble resin is preferably a homopolymer containing an acid group on a main chain and/or a side chain of the polymer, a copolymer of the homopolymer, or a mixture thereof. In addition, the term “water-insoluble” means that the resin is not dissolved or swelled in water of a pH of from 6.0 to 8.0.

The water-insoluble but alkali-soluble resin having an acid group preferably has a functional group such as a phenolic hydroxyl group, a carboxyl group, a sulfonic acid group, a phosphoric acid group, a sulfonamide group, or an active imide group. Therefore, such a resin may be preferably produced by copolymerizing a monomer mixture containing 1 or more ethylenic unsaturated monomers having the above-mentioned functional groups. Preferable examples of the ethylenic unsaturated monomer having the above-mentioned functional group include acrylic acid, methacrylic acid, the compounds represented by the following formulae, and a mixture thereof. In the following formulae, R⁴ represents a hydrogen atom or a methyl group.

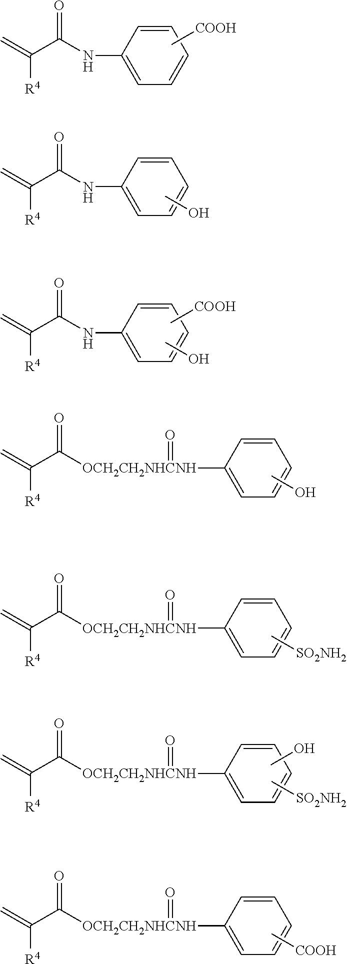

The water-insoluble but alkali-soluble resin usable in the present invention is preferably a polymer compound that is obtained by copolymerizing the above polymerizable monomer with another additional polymerizable monomer. Regarding the copolymerization ratios in such a case, it is preferable that a monomer capable of imparting alkali-solubility such as a monomer having a functional group such as a phenolic hydroxyl group, a carboxyl group, a sulfonic acid group, a phosphoric acid group, a sulfonamide group, or an active imide group, be contained at 10 mol % or more, and more preferably contained at 20 mol % or more. When the copolymerization ratio of the monomer capable of imparting alkali-solubility is 10 mol % or more, the alkali-solubility is sufficiently obtained, and the developability becomes excellent.

Examples of usable additional polymerizable monomers include:

alkyl acrylates or alkyl methacrylates, such as methyl acrylate, ethyl acrylate, propyl acrylate, benzyl acrylate, methyl methacrylate, ethyl methacrylate, cyclohexyl methacrylate, or benzyl methacrylate;

acrylic acid esters and methacrylic acid esters having an aliphatic hydroxyl group, such as 2-hydroxyethyl acrylate or 2-hydroxyethyl methacrylate;

acrylamides or methacrylamides such as acrylamide, methacrylamide, N-methyl acrylamide, N-ethyl acrylamide, or N-phenyl acrylamide;

vinyl esters such as vinyl acetate, vinyl chloroacetate, vinyl butyrate, or vinyl benzoate;

styrenes such as styrene, α-methyl styrene, methyl styrene, or chloromethyl styrene;

other nitrogen atom-containing monomers such as N-vinyl pyrrolidone, N-vinyl pyridine, acrylonitrile, or methacrylonitrile; and

maleimides such as N-methyl maleimide, N-ethyl maleimide, N-propyl maleimide, N-butyl maleimide, N-phenyl maleimide, N-2-methylphenyl maleimide, N-2,6-diethylphenyl maleimide, N-2-chlorophenyl maleimide, N-cyclohexyl maleimide, N-lauryl maleimide, or N-hydroxyphenyl maleimide.

Among these additional ethylenic unsaturated monomers, (meth)acrylic acid esters, (meth)acrylamides, maleimides, and (meth)acrylonitrile are preferably used.

As the water-insoluble but alkali-soluble resin, a novolac resin, a phenol resin, a cresol resin, and a xylenol resin are preferable, and among these, a novolac resin and a phenol resin are more preferable.

The water-insoluble but alkali-soluble resin preferably has a mass average molecular weight of 2,000 or more and a number average molecular weight of 500 or more, and more preferably has a mass average molecular weight of from 5,000 to 300,000 and a mass average molecular weight of from 800 to 250,000. In addition, the dispersity (mass average molecular weight/number average molecular weight) of the water-insoluble but alkali-soluble resin is preferably from 1.1 to 10.

The water-insoluble but alkali-soluble resin contained in the upper layer of the positive-working image recording layer of the present invention may be used alone, or in combination of two or more types thereof.

The content of the water-insoluble but alkali-soluble resin in the upper layer in the present invention is preferably from 2.0% by mass to 99.5% by mass, more preferably from 10.0% by mass to 99.0% by mass, and even more preferably from 20.0% by mass to 90.0% by mass, based on the total solid content of the upper layer.

When the amount of the water-insoluble but alkali-soluble resin added is 2.0% by mass or more, the durability of the recording layer (photosensitive layer) becomes excellent, and when the amount is 99.5% by mass or less, both the sensitivity and durability become excellent.

Other Additives which May be Added to Upper and Lower Layers of Positive-Working Image Recording Layer Having Multilayer Structure

In forming the upper and lower layers, various other additives may be added in addition to the above-mentioned various components, as long as the effects of the present invention are not impaired. The additives described below, for example, may be added only to the upper layer or the lower layer, or may be added to both the layers.

Development Accelerator

For the purpose of improving sensitivity, acid anhydrides, phenols, or organic acids may be added to the upper layer and/or the lower layer.

As the acid anhydrides, a cyclic acid anhydride is preferable. Specific examples of the cyclic acid anhydride usable in the invention include phthalic anhydride, tetrahydrophthalic anhydride, hexahydrophthalic anhydride, 3,6-endoxytetrahydrophthalic anhydride, tetrachlorophthalic anhydride, maleic anhydride, a chloromaleic anhydride, α-phenyl maleic anhydride, succinic anhydride, and pyromellitic anhydride. Examples of acyclic acid anhydride include acetic anhydride.

Examples of phenols include bisphenol A, 2,2′-bishydroxysulfone, p-nitrophenol, p-ethoxyphenol, 2,4,4′-trihydroxybenzophenone, 2,3,4-trihydroxybenzophenone, 4-hydroxybenzophenone, 4,4′,4″-trihydroxytriphenylmethane, and 4,4′3″,4″-tetrahydroxy-3,5,3′,5′-tetramethyltriphenylmethane.

Examples of organic acids include those disclosed in JP-A No. 60-88942, JP-A No. 2-96755, and the like. Specific examples of the organic acids include p-toluenesulfonic acid, dodecylbenzenesulfonic acid, p-toluenesulfinic acid, ethyl sulfate, phenyl phosphonate, phenyl phosphinate, phenyl phosphate, diphenyl phosphate, benzoic acid, isophthalic acid, adipic acid, p-toluic acid, 3,4-dimethoxybenzoic acid, phthalic acid, terephthalic acid, 4-cyclohexene-1,2-dicarboxylic acid, erucic acid, lauric acid, n-undecanoic acid, and ascorbic acid.

The proportion (total proportion when two or more types are used) of the acid anhydrides, phenols, and organic acids in the lower layer or upper layer is preferably from 0.05% by mass to 20% by mass, more preferably from 0.1% by mass to 15% by mass, and particularly preferably from 0.1% by mass to 10% by mass, with respect to the total solid content in the lower or upper layer.

Surfactant

In order to improve coating properties or to attain the stability of the treatment in various development conditions, nonionic surfactants as disclosed in JP-A No. 62-251740 or JP-A No. 3-208514, amphoteric surfactants as disclosed in JP-A No. 59-121044 or JP-A No. 4-13149, or fluorine-containing monomer copolymers as disclosed in JP-A No. 62-170950, JP-A No. 11-288093, or JP-A No. 2003-57820 may be added to the upper layer and/or the lower layer.

Specific examples of the nonionic surfactant include sorbitan tristearate, sorbitan monopalmitate, sorbitan trioleate, stearic acid monoglyceride, and polyoxyethylene nonylphenyl ether.

Specific examples of the amphoteric surfactant include alkyl di(aminoethyl)glycine, an alkyl polyaminoethyl glycine hydrochloric acid salt, 2-alkyl-N-carboxyethyl-N-hydroxyethyl imidazolinium betaine, and N-tetradecyl-N,N-betaine surfactants (for example, “AMOGEN K”, trade name, produced by Dai-ichi Kogyo Seiyaku Co., Ltd.).

The proportion of the surfactant in the lower layer or upper layer is preferably from 0.01% by mass to 15% by mass, more preferably from 0.01% by mass to 5% by mass, and even more preferably from 0.05% by mass to 2.0% by mass, with respect to the total solid content of the lower or upper layer.

Printing Agent and Colorant

A printing agent that is used for obtaining a visible image immediately after heating by light exposure, a dye or pigment as an image colorant, or the like may further be added to the upper layer and/or the lower layer.

The printing agent and the colorant are disclosed in detail in, for example, Paragraphs [0122] and [0123] of JP-A No. 2009-229917, and the compounds disclosed in these paragraphs may be applied to the present invention.

The proportion of the printing agent, colorant, or the like (total amount thereof when two or more types thereof are used) is added preferably at a proportion of from 0.01% by mass to 10% by mass, and more preferably at a proportion of from 0.1% by mass to 3% by mass, based on the total solid content of the lower layer or the upper layer.

Plasticizer

In order to impart flexibility or the like of a coating film, a plasticizer may be added to the upper layer and/or the lower layer. For example, an oligomer, a polymer, or the like of butyl phthalyl, polyethylene glycol, tributyl citrate, diethyl phthalate, dibutyl phthalate, dihexyl phthalate, dioctyl phthalate, tricresyl phosphate, tributyl phosphate, trioctyl phosphate, tetrahydrofurfuryl oleate, acrylic acid, methacrylic acid, or the like may be used.

The plasticizer is added preferably at a proportion (total amount when two or more types thereof are used) of from 0.5% by mass to 10% by mass, and more preferably at a ratio of from 1.0% by mass to 5% by mass, based on total solid content of the lower layer or the upper layer.

Waxing Agent

For the purpose of imparting resistance to scratches, a compound that is capable of reducing a coefficient of static friction of the surface may also be added to the upper layer. Specific examples thereof includes compounds containing an ester of long-chain alkyl carboxylic acid, such as those disclosed in the specification of U.S. Pat. No. 6,117,913, JP-A No. 2003-149799, JP-A No. 2003-302750, and JP-A No. 2004-12770.

The waxing agent is preferably added at such an amount that the proportion of the waxing agent in the upper layer becomes preferably from 0.1% by mass to 10% by mass, and more preferably from 0.5% by mass to 5% by mass.

Respective Components Contained in Positive-Working Image Recording Layer Having Single Layer Structure

The recording layer of the planographic printing plate precursor of the present invention is not limited to the multilayer structure described above, and may have a single layer structure. In a case of the single layer structure, the image recording layer contains at least the (B) copolymer and the (A) infrared absorber, and may optionally contain the additional components described above.

Respective Components Contained in Negative-Working Image Recording Layer Polymerization Initiator

A negative-working image recording layer contains a polymerization initiator (hereinbelow, may be referred to as a “initiator compound”). In the present invention, a radical polymerization initiator is preferably used.

As the initiator compound in the present invention, compounds known to a person skilled in the art may be used without limitation. Specific examples of the compound include a trihalomethyl compound, a carbonyl compound, an organic peroxide, an azo compound, an azide compound, a metallocene compound, a hexaarylbiimidazole compound, an organic boron compound, a disulfone compound, an oxime ester compound, an onium salt compound, and an iron arene complex. Among these, at least one kind selected from the group consisting of a hexaarylbiimidazole compound, an onium salt, trihalomethyl compound, and a metallocene compound is preferable, and a hexaarylbiimidazole compound and an onium salt are particularly preferable.

The polymerization initiators may be used alone, or two or more kinds thereof may be appropriately used concurrently.

Examples of the hexaarylbiimidazole compound include lophine dimers disclosed in EP Patent No. 24629, EP Patent No. 107792, and U.S. Pat. No. 4,410,621, such as 2,2′-bis(o-chlorophenyl)-4,4′,5,5′-tetraphenyl biimidazole, 2,2′-bis(o-bromophenyl)-4,4′,5,5′-tetraphenyl biimidazole, 2,2′-bis(o,o′-dichlorophenyl)-4,4′,5,5′-tetraphenyl biimidazole, 2,2′-bis(o-chlorophenyl)-4,4′,5,5′-tetra(m-methoxyphenyl)biimidazole, 2,2′-bis(o,o′-dichlorophenyl)-4,4′,5,5′-tetraphenyl biimidazole, 2,2′-bis(o-nitrophenyl)-4,4′,5,5′-tetraphenyl biimidazole, 2,2′-bis(o-methylphenyl)-4,4′,5,5′-tetraphenyl biimidazole, and 2,2′-bis(o-trifluoromethylphenyl)-4,4′,5,5′-tetraphenyl biimidazole.

It is particularly preferable that the hexaarylbimidazole compound be used in combination with a sensitizing dye showing maximum absorption at 300 nm to 450 nm.

As the onium salt preferably used in the present invention, a sulfonium salt, an iodonium salt, and a diazonium salt are preferably used. Particularly, a diaryl iodonium salt, and a triaryl sulfonium salt are preferably used. It is particularly preferably that the onium salt be used in combination with an infrared absorber showing maximum absorption at 750 nm to 1400 nm.

As other polymerization initiators, polymerization initiators disclosed in Paragraphs [0071] to [0129] of JP-A No. 2007-206217 may be preferably used.

Preferably, the polymerization initiators in the present invention may be used alone, or two or more kinds thereof may be used concurrently.

The amount of the polymerization initiator (total amount when two or more polymerization initiators are used) used in the image recording layer in the present invention is preferably from 0.01% by mass to 20% by mass, more preferably from 0.1% by mass to 15% by mass, and even more preferably from 1.0% by mass to 10% by mass, based on the total solid content of the negative-working image recording layer.

Polymerizable Compound

The negative-working image recording layer contains a polymerizable compound.

The polymerizable compound used for the negative-working image recording layer is an addition-polymerizable compound having at least one ethylenic unsaturated double bond, and selected from compounds having at least one and more preferably having two or more terminal ethylenic unsaturated bonds. These compounds take, for example, chemical forms of a monomer and prepolymer, that is, a dimer, a trimer, and an oligomer, or a mixture thereof. Examples of the monomer include unsaturated carboxylic acid (for example, acrylic acid, methacrylic acid, itaconic acid, crotonic acid, isocrotonic acid, or maleic acid) and esters and amides thereof. Among these, an ester of unsaturated carboxylic acid and a polyhydric alcohol compound and amides of unsaturated carboxylic acid and a polyhydric alcohol compound are preferably used. In addition, products of an addition reaction between an unsaturated carboxylic acid ester or amides having a nucleophilic substituent such as a hydroxyl group, an amino group, or a mercapto group and monofunctional or polyfunctional isocyanates or epoxies, products of a dehydration condensation reaction between the above unsaturated carboxylic acid ester or amides and monofunctional or polyfunctional carboxylic acid, and the like are preferably used. Moreover, products of an addition reaction between an unsaturated carboxylic acid ester or amides having an electrophilic substituent such as an isocyanate group or an epoxy group and monofunctional or polyfunctional alcohols, amines, or thiols, and products of a substitution reaction between an unsaturated carboxylic acid ester or amides having an eliminable substituent such as a halogen group or a tosyloxy group and monofunctional or polyfunctional alcohols, amines, or thiols are also preferable. As other examples, instead of the unsaturated carboxylic acid, compound groups substituted with unsaturated phosphonic acid, styrene, vinyl ether, and the like can also be used. Examples of these compounds are disclosed in documents such as JP-T No. 2006-508380, JP-A No. 2002-287344, JP-A No. 2008-256850, JP-A No. 2001-342222, JP-A No. 9-179296, JP-A No. 9-179297, JP-A No. 9-179298, JP-A No. 2004-294935, JP-A No. 2006-243493, JP-A No. 2002-275129, JP-A No. 2003-64130, JP-A No. 2003-280187, and JP-A No. 10-333321.

Specific examples of the monomer of an ester of a polyhydric alcohol and an unsaturated carboxylic acid include: acrylic acid esters such as ethylene glycol diacrylate, 1,3-butanediol diacrylate, tetramethylene glycol diacrylate, propylene glycol diacrylate, trimethylolpropane triacrylate, hexanediol diacrylate, tetraethylene glycol diacrylate, pentaerythritol tetraacrylate, sorbitol triacrylate, isocyanuric acid ethylene oxide (EO)-modified triacrylate, or a polyester acrylate oligomer; methacrylic acid esters such as tetramethylene glycol dimethacrylate, neopentyl glycol dimethacrylate, trimethylolpropane trimethacrylate, ethylene glycol dimethacrylate, pentaerythritol trimethacrylate, bis-[p-(3-methacryloxy-2-hydroxypropoxy)phenyl]dimethyl methane, or bis-[p-(methacryloxyethoxy)phenyl]dimethyl methane. Specific examples of the monomer of an amide of a polyvalent amine compound and an unsaturated carboxylic acid include methylene bis-acrylamide, methylene bis-methacrylamide, 1,6-hexamethylene bis-acrylamide, 1,6-hexamethylene bis-methacrylamide, diethylenetriamine tris-acrylamide, xylylene bis-acrylamide, and xylylene bis-methacrylamide.

In addition, a urethane addition-polymerizable compound produced by an addition reaction between isocyanate and a hydroxyl group is also preferable. Specific examples of the compound include a vinyl urethane compound having two or more polymerizable vinyl groups in a single molecule as disclosed in JP-B No. 48-41708, which is obtained by adding a hydroxyl group-containing vinyl monomer represented by the following Formula (A) to a polyisocyanate compound having two or more isocyanate groups in a single molecule.

CH₂═C(R⁴)COOCH₂CH(R⁵)OH Formula (A)

In Formula (A), R⁴ and R⁵ each independently represent a hydrogen atom or CH₃.

Furthermore, urethane acrylates disclosed in JP-A No. 51-37193, JP-B No. 2-32293, JP-B No. 2-16765, JP-A No. 2003-344997, and JP-A No. 2006-65210, urethane compounds having an ethylene oxide skeleton disclosed in JP-B No. 58-49860, JP-B No. 56-17654, JP-B No. 62-39417, JP-B No. 62-39418, JP-A No. 2000-250211, and JP-A No. 2007-94138, and urethane compounds having a hydrophilic group disclosed in U.S. Pat. No. 7,153,632, JP-T No. 8-505958, JP-A No. 2007-293221, and JP-A No. 2007-293223 are also preferable.

The details regarding how to use these compounds, such as the structures of these polymerizable compounds, whether these compounds are used alone or used concurrently, the amount to be added, and the like may be arbitrarily decided according to the final performance design of the planographic printing plate precursor.

The polymerizable compound is used preferably in a range of from 5% by mass to 75% by mass, more preferably in a range of from 25% by mass to 70% by mass, and particularly preferably in a range of from 30% by mass to 60% by mass, based on the total solid content of the negative-working image recording layer.

Hereinbelow, the method of forming the image recording layer having a positive-working multilayer structure, the image recording layer having a positive-working single layer structure, and the negative-working image recording layer will be described in detail.

### Formation of Lower Layer and Upper Layer of Image Recording Layer Having Positive-Working Multilayer Structure

In general, an upper or lower layer of the planographic printing plate precursor of the present invention may be formed by dissolving the respective components in a solvent and applying the resultant coating liquid onto an appropriate hydrophilic support.

Examples of the solvent to be used herein include ethylene dichloride, cyclohexanone, methyl ethyl ketone, methanol, ethanol, propanol, ethylene glycol monomethyl ether, 1-methoxy-2-propanol, 2-methoxyethyl acetate, 1-methoxy-2-propyl acetate, dimethoxyethane, methyl lactate, ethyl lactate, N,N-dimethyl acetamide, N,N-dimethyl formamide, tetramethyl urea, N-methylpyrrolidone, dimethyl sulfoxide, sulfolane, γ-butyrolactone, and toluene, but the present invention is not limited thereto. These solvents may be used alone, or a mixture of two or more thereof may be used.

In principle, it is preferable to separately form the two layers of a lower layer and an upper layer.

Examples of methods of separately forming the two layers include a method utilizing a difference in solvent solubility between the components contained in the lower layer and the components contained in the upper layer.

Examples of other methods of separately forming the two layers include a method of rapidly drying and removing a solvent after an upper layer has been formed by coating. When these methods are used concurrently, the layers are more reliably separated.

Hereinbelow, these methods will be described in detail, but the method of separately coating the two layers which is usable in the invention is not limited thereto.

In a method of utilizing a difference in solvent solubility between the components contained in the lower layer and the components contained in the upper layer, a coating liquid for forming an upper layer contains a solvent system that do not dissolve any of the components contained in a lower layer. Accordingly, even when two layers are formed, the respective layers are clearly separated from each other. For example, components that are insoluble in a solvent such as methyl ethyl ketone or 1-methoxy-2-propanol that dissolves the alkali-soluble resin which is an upper layer component may be selected as the lower layer components, a coating liquid containing a solvent system capable of dissolving the lower layer components may be coated and dried to form a lower layer, and then an upper layer containing the alkali-soluble resin as a main component may be formed by coating and drying a coating liquid containing methyl ethyl ketone or 1-methoxy-2-propanol, whereby two layers are be formed.

The method of extremely rapidly drying the solvent after the second layer (upper layer) has been coated may be carried out by blowing high-pressure air from a slit nozzle that is disposed at an almost right angle to the running direction of a web, supplying heat energy as conductive heat from the bottom surface of a web by a roll (heating roll) in which a heating medium such as vapor has been supplied, or combining these methods.

The coating amount of the lower layer components after drying that are coated onto a hydrophilic support of the planographic printing plate precursor of the present invention is preferably in a range of from 0.5 g/m² to 4.0 g/m², and more preferably in a range of from 0.6 g/m² to 2.5 g/m². When the amount is 0.5 g/m² or more, printing durability becomes excellent, and when the amount is 4.0 g/m² or less, image reproducibility and sensitivity become excellent.

The coating amount of the upper layer components after drying is preferably in a range of from 0.05 g/m² to 1.0 g/m², and more preferably in a range of from 0.08 g/m² to 0.7 g/m². When the amount is 0.05 g/m² or more, development latitude and scratch resistance become excellent, and when the amount is 1.0 g/m² or less, sensitivity becomes excellent.

The total coating amount of the lower and upper layers after drying is preferably in a range of from 0.6 g/m² to 4.0 g/m², and more preferably in a range of from 0.7 g/m² to 2.5 g/m². When the amount is 0.6 g/m² or more, printing durability becomes excellent, and when the amount is 4.0 g/m² or less, image reproducibility and sensitivity become excellent.

Formation of Image Recording Layer of Positive-Working Single Layer Structure

The positive-working image recording layer of the planographic printing plate precursor of the present invention is not limited to the multilayer structure and may have a single layer structure.

Similarly to the formation of the upper and lower layers of the multilayer structure, the single layer positive-working image recording layer may be formed by dissolving the respective components in a solvent and coating this solvent by an arbitrary coating method.

The coating amount after drying in a case of the positive-working image recording layer of the single layer structure is preferably in a range of from 0.6 g/m² to 4.0 g/m², and more preferably in a range of from 0.7 g/m² to 2.5 g/m². When the amount is 0.6 g/m² or more, printing durability becomes excellent, and when the amount is 4.0 g/m² or less, image reproducibility and sensitivity become excellent.

Formation of Negative-Working Image Recording Layer

Similarly to the above, the negative-working image recording layer may be formed by dissolving the respective components in a solvent, and coating this solvent by an arbitrary coating method.

The amount (solid content) of the image recording layer coated on a hydrophilic support obtained after coating and drying is preferably in a range of from 0.6 g/m² to 4.0 g/m², and more preferably in a range of from 0.7 g/m² to 2.5 g/m². When the amount is 0.6 g/m² or more, printing durability becomes excellent, and when the amount is 4.0 g/m² or less, image reproducibility and sensitivity become excellent.

Hydrophilic Support

As the hydrophilic support used for the planographic printing plate precursor of the present invention, a polyester film or an aluminum plate is preferable. Among these, an aluminum plate is particularly preferable because it has excellent dimensional stability and is relatively inexpensive. Preferable aluminum plates are a pure aluminum plate and an alloy plate that has aluminum as main components and contains a trace of different elements. It is also preferable to use a plastic film to which aluminum has been laminated or vapor-deposited. Examples of the different elements contained in the aluminum alloy include silicon, iron, manganese, copper, magnesium, chromium, zinc, bismuth, nickel, and titanium. The content of the different elements in the alloy is preferably 10% by mass or less.

The particularly preferable aluminum in the present invention is pure aluminum. However, it is difficult to produce completely pure aluminum from the viewpoint of a refining technique, so different elements may be contained to a slight extent.

The aluminum plate applied to the present invention is not limited in terms of the composition, and it is possible to appropriately use an aluminum plate formed of a material known and widely used in the related art. The thickness of the aluminum plate used in the present invention is preferably from 0.1 mm to 0.6 mm, more preferably from 0.15 mm to 0.4 mm, and particularly preferably from 0.2 mm to 0.3 mm.

Such an aluminum plate may be optionally subjected to a surface treatment such as surface roughening treatment or an anodization treatment. In the surface treatment for the aluminum support, for example, a degreasing treatment using a surfactant, an organic solvent, or an aqueous alkali solution, a surface roughening treatment, an anodization treatment, and the like are appropriately performed, as disclosed in detail in Paragraphs [0167] to [0169] of JP-A No. 2009-175195.

The surface of aluminum having undergone the anodization treatment is optionally subjected to a hydrophilizing treatment.

As the hydrophilizing treatment, an alkali metal silicate (for example, an aqueous sodium silicate solution) method, a method of treating by using zirconium potassium fluoride or polyvinylsulfonic acid, or the like may be used, as disclosed in Paragraph [0169] of JP-A No. 2009-175195.

Undercoat Layer

In the present invention, an undercoat layer may optionally be formed between the hydrophilic support and the lower layer, or between the hydrophilic support and the image recording layer in a case of a single layer structure.

As the undercoat layer components, various organic compounds are used, and preferable examples thereof include phosphonic acids having an amino group, such as carboxy methyl cellulose and dextrin, organic phosphonic acids, organic phosphoric acids, organic phosphinic acids, and amino acids, a hydrochloric acid salt of an amine having a hydroxyl group. These undercoat layer components may be used alone, or two or more kinds thereof may be used as a mixture. The detail of compounds used for the undercoat layer and a method of forming the undercoat layer are disclosed, for example, in Paragraphs [0171] and [0172] of JP-A No. 2009-175195, the disclosure of which is applied to the present invention.

The coating amount of the organic undercoat layer is preferably from 2 mg/m² to 200 mg/m², and more preferably from 5 mg/m² to 100 mg/m². When the coated amount is within these ranges, sufficient printing durability is obtained.

Backcoat Layer

A backcoat layer may optionally be provided to the rear surface of the hydrophilic support of the planographic printing plate precursor of the present invention. As the backcoat layer, coating layer's are preferably used which include a metal oxide obtained by hydrolysis or polycondensation of the organic polymer compound disclosed in JP-A No. 5-45885 and the organic or inorganic metal compound disclosed in JP-A No. 6-35174. Among these coating layers, alkoxy compounds of silicon such as Si(OCH₃)₄, Si(OC₂H₅)₄, Si(OC₃H₇)₄, and Si(OC₄H₉)₄ are particularly preferable from the viewpoints that these compounds are inexpensive and easily available, and that the coating layer of the metal oxide obtained from these compounds is excellently resistant to a developer.

The planographic printing plate precursor produced in the above manner is subjected to imagewise light exposed, followed by a development treatment.

Protective Layer

In the planographic printing plate precursor of the present invention, a protective layer may optionally be provided on the negative-working image recording layer. Such a planographic printing plate precursor is generally exposed in the atmosphere. The protective layer prevents a low-molecular weight compound such as oxygen or a basic substance in the atmosphere inhibiting an image forming reaction caused by exposure performed in a photosensitive layer from being mixed into the photosensitive layer, thereby making it possible to perform the exposure in the atmosphere. Accordingly, it is desired for the protective layer to have characteristics in which the protective layer shows low permeability with respect to the low-molecular weight compound such as oxygen. In addition, it is desired that the protective layer show excellent adhesiveness to the photosensitive layer without substantially hindering permeation of the light used for the exposure, and can be easily removed in the step of developing after the exposure.

As materials usable for the protective layer, it is preferable to use, for example, water-soluble polymer compounds showing relatively excellent crystallinity. Specifically, water-soluble polymers such as polyvinyl alcohol, polyvinyl pyrrolidone, acidic celluloses, gelatin, gum Arabic, and polyacrylic acid are known. Among these, polyvinyl alcohol is particularly preferable, because when polyvinyl alcohol is used as a main component, the extremely excellent results are yielded in regard to basic characteristics such as an oxygen shielding property and removability in development. A portion of the polyvinyl alcohol used for the protective layer may be substituted with an ester, an ether, or an acetal, as long as the polyvinyl alcohol contains an unsubstituted vinyl alcohol unit to have the oxygen shielding property and water-solubility required. Similarly, a portion of the polyvinyl alcohol may contain other copolymerization components.

Examples of the polyvinyl alcohol include those hydrolyzed 71% to 100% and having a molecular weight in a range of from 300 to 2,400. Specific examples thereof include PVA-105, PVA-110, PVA-117, PVA-117H, PVA-120, PVA-124, PVA-124H, PVA-CS, PVA-CST, PVA-HC, PVA-203, PVA-204, PVA-205, PVA-210, PVA-217, PVA-220, PVA-224, PVA-217EE, PVA-217E, PVA-220E, PVA-224E, PVA-405, PVA-420, PVA-613, and L-8 (all trade names, manufactured by Kurary Co., Ltd.).

It is preferable that the protective layer in the planographic printing plate precursor of the present invention contain an inorganic laminar compound, for the purpose of improving the oxygen shielding property and a property of protecting image recording layer surface. Among the inorganic laminar compounds, fluorine-containing, swellable synthetic mica which is a synthetic inorganic laminar compound is particularly useful. Specifically, preferable examples thereof include an inorganic laminar compound disclosed in JP-A No. 2005-119273.

Method of Producing Planographic Printing Plate

The method of producing a planographic printing plate of the present invention includes an imagewise light exposure step of exposing the photosensitive planographic printing plate precursor of the present invention to light in the form of an image, and a development step of developing the planographic printing plate precursor after the light exposure.

According to the method of producing a planographic printing plate of the present invention, the developability change becomes excellent, and the obtained planographic printing plate is free from stains caused by the film remaining in the non-image portion and excellent in the strength of the image portion and durability.

Hereinbelow, the respective steps of the method of preparing a planographic printing plate of the present invention will be described in detail.

Light Exposure Step

The method of producing a planographic printing plate of the present invention includes a step of exposing the photosensitive planographic printing plate precursor of the present invention to light in the form of an image (i.e., light exposure step).

As a light source of active light rays used for the imagewise light exposure of the planographic printing plate precursor of the present invention, a light source having an emission wavelength in a region ranging from near infrared to infrared is preferable, and a solid-state laser and a semiconductor laser are more preferable. Among these, in the present invention, it is particularly preferable to perform image exposure by using a solid-state laser or a semiconductor laser capable of radiating infrared rays having a wavelength of from 750 nm to 1,400 nm.

The laser output is preferably 100 mW or greater, and in order to shorten the exposure time, it is preferable to use a multibeam laser device. The exposure time per pixel is preferably within 20 μsec.

The energy applied to the planographic printing plate precursor is preferably from 10 mJ/cm² to 300 mJ/cm². Within this range, the precursor is cured sufficiently, and the laser ablation is inhibited, whereby the image is prevented from being damaged.

In the present invention, it is possible to overlap light beams of the light source to performing exposure. The “overlap” means that a sub-scanning pitch width is smaller than a beam diameter. For example, provided that a beam diameter is expressed as a full width at half maximum (FWHM) of the beam intensity, the overlap can be quantitatively expressed as FWHM/sub-scanning pitch width (overlap coefficient). In the present invention, the overlap coefficient is preferably 0.1 or greater.

The scanning method of the light source of an exposure device usable in the present invention is not particularly limited, and an outer cylindrical surface scanning method, an inner cylindrical surface scanning method, a plane scanning method, or the like may be used. The channel of the light source may be either a single channel or a multichannel, but in a case of the outer cylindrical surface scanning method, a multichannel is preferably used.

Development Step

### Developer

The method of producing a planographic printing plate of the present invention includes a development step using an aqueous alkali solution. The aqueous alkali solution (hereinbelow, also referred to as a “developer”) used for the development step is an aqueous alkali solution preferably having a pH of from 8.5 to 10.8, and more preferably having a pH of from 9.0 to 10.0. The developer preferably contains a surfactant, and more preferably contains at least an anionic surfactant or a nonionic surfactant. The surfactant contributes to the improvement in processability. The pH herein refers to a value measured at room temperature (25° C.) using F-51 (trade name, manufactured by HORIBA).

As the surfactant used for the developer, any of the anionic, nonionic, cationic, and amphoteric surfactants may be used, but as described above, the anionic and nonionic surfactants are preferable.

The anionic surfactant used for the developer of the present invention is not particularly limited, and examples thereof include fatty acid salts, abietic acid salts, hydroxyalkanesulfonic acid salts, alkanesulfonic acid salts, dialkylsulfosuccinic acid salts, linear alkylbenzenesulfonic acid salts, branched alkylbenzenesulfonic acid salts, alkylnaphthalenesulfonic acid salts, alkyl diphenyl ether (di)sulfonic acid salts, alkyl phenoxypolyoxy ethylene propyl sulfonic acid salts, polyoxyethylene alkylsulfophenyl ether salts, sodium N-methyl-N-oleyl taurine salts, monoamide disodium N-alkylsulfosuccinic acid salts, petroleum sulfonic acid salts, sulfated castor oil, sulfated beef tallow oil, sulfuric acid ester salts of fatty acid alkyl ester, alkyl sulfuric acid ester salts, poloxyethylene alkyl ether sulfuric acid ester salts, fatty acid monoglyceride sulfuric acid ester salts, polyoxyethylene alkylphenyl ether sulfuric acid ester salts, polyoxyethylene styrylphenyl ether sulfuric acid ester salts, alkyl phosphoric acid ester salts, polyoxyethylene alkyl ether phosphoric acid ester salts, polyoxyethylene alkylphenyl ether phosphoric acid ester salts, partially saponified products of a styrene-maleic anhydride copolymer, partially saponified products of an olefin-maleic anhydride copolymer, and naphthalene sulfonic acid salt formalin condensates. Among these, alkylbenzenesulfonic acid salts, alkylnaphthalenesulfonic acid salts, and alkyl diphenyl ether (di)sulfonic acid salts are particularly preferably used.

The cationic surfactant used for the developer of the present invention is not particularly limited, and those known in the related art may be used. Examples thereof include alkylamine salts, quaternary ammonium salts, polyoxyethylene alkylamine salts, and polyethylene polyamine derivatives.

The nonionic surfactant used for the developer of the present invention is not particularly limited, and examples thereof include a polyethylene glycol higher alcohol ethylene oxide adduct, an alkylphenol ethylene oxide adduct, an alkylnaphthol ethylene oxide adduct, a phenol ethylene oxide adduct, a naphthol ethylene oxide adduct, a fatty acid ethylene oxide adduct, a polyhydric alcohol fatty acid ester ethylene oxide adduct, a higher alkylamine ethylene oxide adduct, a fatty acid amide ethylene oxide adduct, an ethylene oxide adduct of fat and oil, a polypropylene glycol ethylene oxide adduct, a dimethyl siloxane-ethylene oxide block copolymer, a dimethyl siloxane-(propylene oxide-ethylene oxide) block copolymer, a fatty acid ester of a polyhydric alcohol type glycerol, a fatty acid ester of pentaerythritol, a fatty acid ester of sorbitol and sorbitan, a fatty acid ester of sucrose, an alkyl ether of polyhydric alcohol, a fatty acid amide of alkanolamines, and the like. Among these, those having an aromatic ring and an ethylene oxide chain are preferable, and an alkyl-substituted or unsubstituted phenol ethylene oxide adduct and an alkyl-substituted or unsubstituted naphthol ethylene oxide adduct are more preferable.

The amphoteric surfactant used for the developer of the present invention is not particularly limited, and examples thereof include surfactants based on amine oxides such as alkyl dimethyl amine oxide, surfactants based on betaines such as alkyl betaine, and surfactants based on amino acids such as sodium alkyl amino fatty acid. Particularly, alkyl dimethyl amine oxide that may have a substituent, alkyl carboxybetaine that may have a substituent, and alkyl sulfobetaine that may have a substituent are preferably used. Specific examples of these compounds are disclosed in Paragraphs [0255] to [0278] of JP-A No. 2008-203359, Paragraphs [0028] to [0052] of JP-A No. 2008-276166, and the like.

In addition, from the viewpoint of the stabilized solubility to water or turbidity, the HLB value is preferably 6 or greater, and more preferably 8 or greater.

As the surfactant used for the developer, anionic and nonionic surfactants are preferable, and anionic surfactants containing sulfonic acid or a sulfonic acid salt and nonionic surfactants having an aromatic ring and an ethylene oxide chain are particularly preferable.

The surfactants may be used alone, or used in combination of two or more thereof.

The content of the surfactant(s) in the developer is preferably from 0.01% by mass to 10% by mass, and more preferably from 0.01% by mass to 5% by mass.

When carbonate ions and hydrogen carbonate ions are contained as a buffer in the developer to keep the developer at a preferable pH, it is possible to inhibit pH fluctuation even if the developer is used for a long time, and to inhibit the developability deterioration and generation of developing gas caused by the fluctuation in pH. In order to cause the developer to contain the carbonate ions and the hydrogen carbonate ions, a carbonate salt and a hydrogen carbonate salt may be added to the developer, or the carbonate ions and the hydrogen carbonate ions may be generated by adjusting pH after the carbonate salt and the hydrogen carbonate salt are added. Though not particularly limited, the carbonate salt and the hydrogen carbonate salt are preferably an alkali metal salt. Examples of alkali metals include lithium, sodium, and potassium, and sodium is particularly preferable. These may be used alone, or two or more kinds thereof may be used in combination.

The total amount of the carbonate salt and the hydrogen carbonate salt is preferably from 0.3% by mass to 20% by mass, more preferably from 0.5% by mass to 10% by mass, and particularly preferably from 1% by mass to 5% by mass, based on the total mass of the developer. When the total amount is 0.3% by mass or more, developability and treatment ability do not deteriorate. When the total amount is 20% by mass or less, precipitates or crystals are not easily generated, and the developer is not easily gelated when neutralized for a waste liquid treatment, so the waste liquid treatment is not disrupted.

For the purpose of finely adjusting alkali concentration and helping the dissolution of the photosensitive layer of a non-image portion, other alkali agents, for examples, organic alkali agents may be concurrently used supplementarily. Examples of the organic alkali agent include monomethylamine, dimethylamine, trimethylamine, monoethylamine, diethylamine, triethylamine, monoisopropylamine, diisopropylamine, triisopropylamine, n-butylamine, monoethanolamine, diethanolamine, triethanolamine, monoisopropanolamine, diisopropanolamine, ethylenimine, ethylenediamine, pyridine, and tetramethyl ammonium hydroxide. These other alkali agents may be used alone or used in combination of two or more thereof.

In addition to the these components, the developer may also contain a moisturizer, a preservative, a chelate compound, an antifoaming agent, an organic acid, an organic solvent, an inorganic acid, an inorganic salt, or the like.

Here, when a water-soluble polymer compound is added, the plate surface tends to becomes tacky, particularly when the developer is exhausted, so it is preferable not to add such a compound.

As a moisturizer, ethylene glycol, propylene glycol, triethylene glycol, butylene glycol, hexylene glycol, diethylene dipropylene glycol, glycerin, trimethylolpropane, diglycerin, or the like may preferably be used. The moisturizer may be used alone, or two or more kinds thereof may be used in combination. The moisturizer is preferably used in an amount of from 0.1% by mass to 5% by mass, based on the total weight of the developer.

As a preservative, phenol or a derivative thereof, formalin, an imidazole derivative, sodium dihydroacetate, a 4-isothiazolin-3-one derivative, benzisothiazolin-3-one, 2-methyl-4-isothiazolin-3-one, a benzotriazole derivative, an amidine guanidine derivative, quaternary ammonium salts, pyridine, quinoline, guanidine, and the derivatives thereof, diazine, a triazole derivative, oxazole, an oxazine derivative, 2-bromo-2-nitropropane-1,3-diol based on nitrobromo alcohol, 1,1-dibromo-1-nitro-2-ethanol, 1,1-dimromo-1-nitro-2-propanol, or the like may be preferably used. It is preferable to use a combination of two or more kinds of preservatives so as to exert an effect on various fungi and to exert a sterilizing effect. The preservative is added in an amount in which effects are stably exerted on germs, fungi, yeast, and the like, and the amount varies with the type of germs, fungi, and yeast. The amount of the preservative(s) is preferably in a range of from 0.01% by mass to 4% by mass, based on the total weight of the developer.

Examples of chelate compounds include ethylene diamine tetraacetate and potassium and sodium salts thereof; diethylene triamine pentaacetate and potassium and sodium salts thereof; triethylene tetramine hexaacetate and potassium and sodium salts thereof; hydroxyethyl ethylene diamine triacetate and potassium and sodium salts thereof; nitrilotriacetic acid and a sodium salt thereof; 1-hydroxyethane-1,1-diphosphoinc acid and potassium and sodium salts thereof; and organic phosphonic acids or phosphonoalkane tricarboxylic acids such as aminotri(methylenephosphonic acid) and potassium and sodium salts thereof. Instead of the sodium and potassium salts of these chelate compounds, an organic amine salt is also effective. As the chelate agent, those stably existing in the developer composition and not hindering printing properties are selected. The amount of the chelate compound added is preferably from 0.001% by mass to 1.0% by mass, based on the total weight of the developer.

As an antifoaming agent, general self-emulsified and emulsified compounds based on silicone and nonionic compounds may be used, and the HLB value of the compound is preferably 5 or less. Silicone antifoaming agents are preferable, and among these, any of emulsified and dispersed compounds and solubilized compounds may be used. The content of the antifoaming agent is preferably in a range of from 0.001% by mass to 1.0% by mass, based on the total weight of the developer.

Examples of organic acid include citric acid, acetic acid, oxalic acid, malonic acid, salicylic acid, caprylic acid, tartaric acid, malic acid, lactic acid, levulinic acid, p-toluenesulfonic acid, xylenesulfonic acid, phytic acid, and organic phosphonic acid. The organic acids may each be used in the form of an alkali metal salt or an ammonium salt thereof. The content of the organic acid is preferably from 0.01% by mass to 0.5% by mass, based on the total weight of the developer.

Examples of organic solvents include aliphatic hydrocarbons (hexane, heptane, ISOPAR E, ISOPAR H, ISOPAR G (trade names, manufactured by Exxon Mobile Chemical), gasoline, kerosene, and the like), aromatic hydrocarbons (toluene, xylene, and the like), halogenated hydrocarbons (methylene dichloride, ethylene dichloride, triclene, monochlorobenzene, and the like), and polar solvents.

Examples of polar solvents include alcohols (methanol, ethanol, propanol, isopropanol, benzyl alcohol, ethylene glycol monomethyl ether, 2-ethoxyethanol, and the like), ketones (methyl ethyl ketone, cyclohexanone, and the like), esters (ethyl acetate, methyl lactate, propylene glycol monomethyl ether acetate, and the like), and others such as triethyl phosphate, tricresyl phosphate, N-phenylethanolamine, or N-phenyldiethanolamine).

When the organic solvent is water-insoluble, the organic solvent may be used after making the organic solvent to be water-soluble using a surfactant or the like. When the developer contains the organic solvent, the concentration of the solvent is preferably less than 40% by mass from the viewpoints of safety and flammability.

Examples of inorganic acids and inorganic salts include phosphoric acid, metaphosphoric acid, primary ammonium phosphate, secondary ammonium phosphate, primary sodium phosphate, secondary sodium phosphate, primary potassium phosphate, secondary potassium phosphate, sodium tripolyphosphate, potassium pyrophosphate, sodium hexametaphosphate, magnesium nitrate, sodium nitrate, potassium nitrate, ammonium nitrate, sodium sulfate, potassium sulfate, ammonium sulfate, sodium sulfite, ammonium sulfite, sodium hydrogen sulfate, and nickel sulfate. The content of the organic salt is preferably from 0.01% by mass to 0.5% by mass, based on the total weight of the developer.

Development Treatment

The development temperature is not particularly limited as long as development is able be to performed, and is preferably 60° C. or lower, and more preferably from 15° C. to 40° C. In a development treatment using an automatic developing machine, the developer is exhausted in accordance with the treated amount in some cases. Accordingly, the treatment performance may be restored by using supplementary developer or new developer. An example of the development and the treatment after the development includes a method of performing alkali development, removing alkali in a post-washing step, performing a gumming treatment in a gum coating step, and drying the resultant in a drying step. Another example preferably includes a method in which pre-washing, developing, and gum coating are simultaneously carried out by using an aqueous solution containing carbonate ions, hydrogen carbonate ions, and a surfactant. Accordingly, the pre-washing step may not be performed, and only one type of developer is used. It is preferable to conduct the pre-washing, developing, and gum coating using a single solution and in one bath, followed by a drying step. After the development, it is preferable to perform drying after the remaining developer has been removed using a squeeze roller or the like.

The development step may be preferably performed using an automatic processor provided equipped with a rubbing member. Examples of the automatic processor include automatic processors capable of performing a rubbing treatment while transporting a planographic printing plate precursor having undergone image exposure, which are disclosed in JP-A No. 2-220061 and JP-A No. 60-59351, and automatic processor capable of performing a rubbing treatment on the planographic printing plate precursor having undergone image exposure that is set on a cylinder while rotating the cylinder, which are disclosed in the specification of U.S. Pat. Nos. 5,148,746 and 5,568,768 and the specification of UK Patent No. 2297719, and the like. Among these, an automatic processor using a rotating brush roll as the rubbing member is particularly preferable.

The rotating brush roll used in the present invention may be appropriately selected in consideration of preventing the image portion from being easily damaged and of the stiffness of the planographic printing plate precursor in the hydrophilic support. As the rotating brush roll, known ones that are formed by implanting a brush material in a plastic or a metal roll can be used. For example, it is possible to use brush rolls disclosed in JP-A No. 58-159533, JP-A No. 3-100554, and Japanese Examined Utility Model Registration Application Publication (JP-UM-B) No. 62-167253, which are formed by radially winding a metallic or plastic, groove-shaped material in which a brush material has been implanted in a line around a plastic or metallic roll to be a core without a gap.

As the brush material, it is possible to use plastic fibers (for example, polyester synthetic fiber such as polyethylene terephthalate, polybutylene terephthalate, polyamide synthetic fiber such as nylon 6.6 and nylon 6.10, polyacryl synthetic fiber such as polyacrylonitrile and polyalkyl (meth)acrylate, and polyolefin synthetic fiber such as polypropylene and polystyrene). For example, fiber having a strand diameter of from 20 μm to 400 μm and a strand length of from 5 μm to 30 mm may be preferably used.

The outer diameter of the rotating brush roll is preferably from 30 mm to 200 mm, and the circumferential speed of the leading end of the brush rubbing the plate surface is preferably from 0.1 m/sec to 5 m/sec. It is preferably to use plural rotating brush rolls.

The rotation direction of the rotating brush roll may be the same or opposite to the transport direction of the planographic printing plate precursor. However, when two or more rotating brush rolls are used, it is preferable that at least one rotating brush roll rotate in the same direction, and at least one rotating brush roll rotate in the opposite direction. In this manner, the photosensitive layer of the non-image portion is more reliably removed. It is also effective to shake the rotating brush roll in the rotation axis direction of the brush roll.

It is preferable to perform the step of drying continuously or discontinuously after the step of developing. The drying is performed by hot air, infrared, far-infrared, and the like.

As the automatic processor that is preferably used in the method of preparing a planographic printing plate of the present invention, a device including a developing unit and a drying unit is used. A planographic printing plate precursor is subjected to the developing and the gum coating in a developing bath and then dried in the drying unit, thereby obtaining a planographic printing plate.

For the purpose of improving the printing durability and the like, it is also possible to heat the printing plate after developing under severe conditions. The heating temperature is generally in a rage of from 200° C. to 500° C. If the temperature is low, a sufficient image strengthening action is not obtained, and if the temperature is too high, there is a concern that a problem that the hydrophilic support deteriorates and that the image portion is thermally decomposed will occur.

The planographic printing plate obtained in this manner is provided to an offset printing machine so as to be preferably used for printing plural sheets of images.

### EXAMPLES

Hereinbelow, the present invention will be described in more detail by referring to examples, but the present invention is not limited thereto. In the following examples, “%” and “part(s)” indicate “% by mass” and “part(s) by mass”, respectively, unless otherwise specified.

### Synthesis Examples

### Synthesis of Acryl Binder (PA-01)

In a three-necked flask, a mixed solution including vinyl acetate (86 g), compound X-1 mentioned below (70 g), and VA-044 (trade name, manufactured by Wako Pure Chemical Industries Co., Ltd.; 2,2′-azobis[2-(2-imidazolin-2-yl)propane]dihydrochloride) was added dropwise over 2.5 hours to pure water (200 g) which had been heated to 80° C. under a nitrogen gas flow.

After completion of the dropwise addition, sodium hydroxide (10 g) was added to the resulting solution, and the mixture was stirred for 5 hours. After that, butyl aldehyde (40 g) and p-toluene sulfonic acid (1 g) were further added thereto, followed by stirring for 5 hours. After completion of the reaction, the resulting solution was added to methanol (3,000 ml) under stirring, and the stirring was continued for 60 minutes, followed by filtration, water washing, and drying, thereby obtaining a binder (PA-01).

The weight average molecular weight (in terms of polystyrene) of the binder PA-01 confirmed by gel permeation chromatography (GPC) was 40,000.

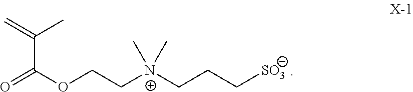

In the same manner as described above, PA-02 to PA-42 and CA01 to CA06 were synthesized. The respective structures and molecular weights thereof are shown below.

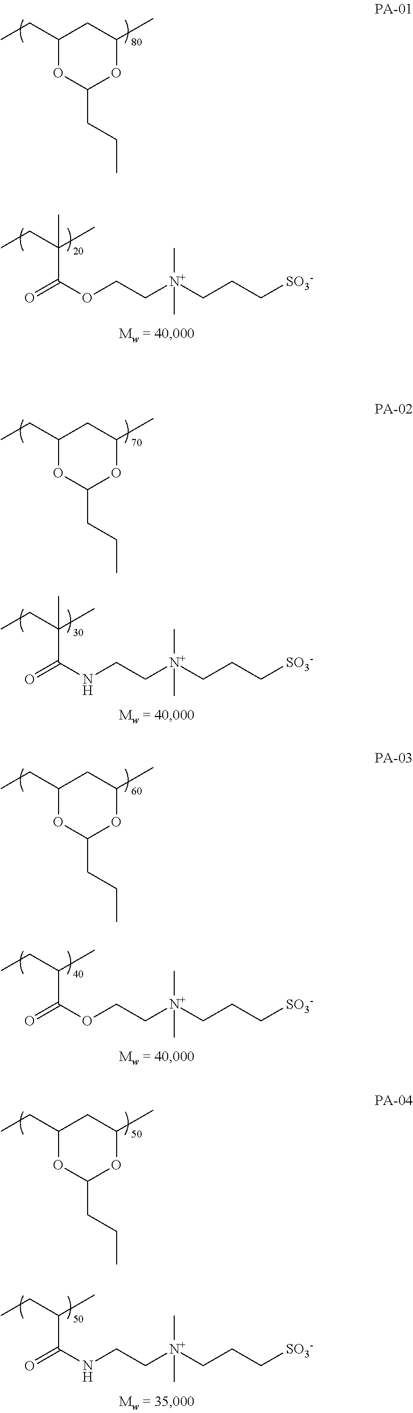

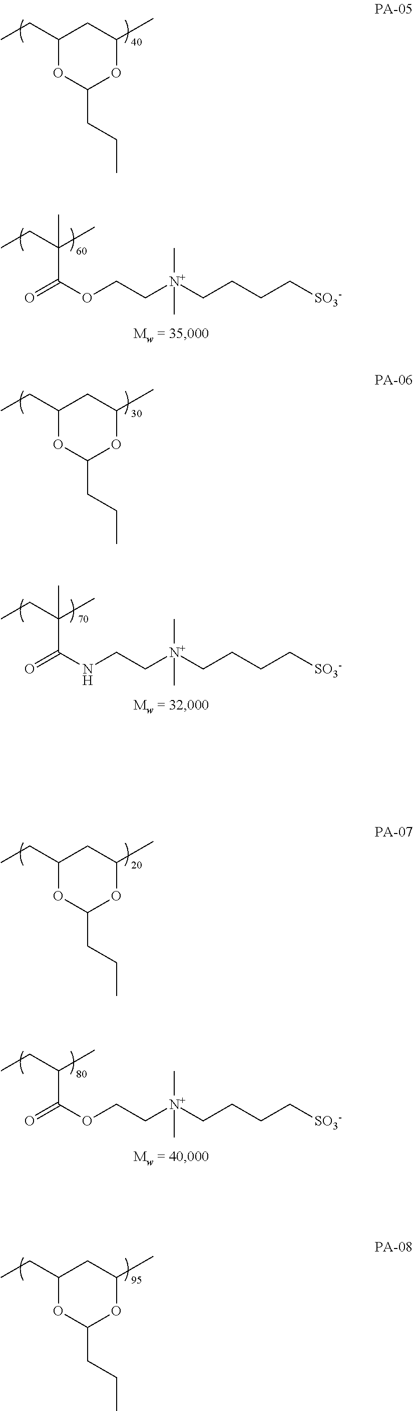

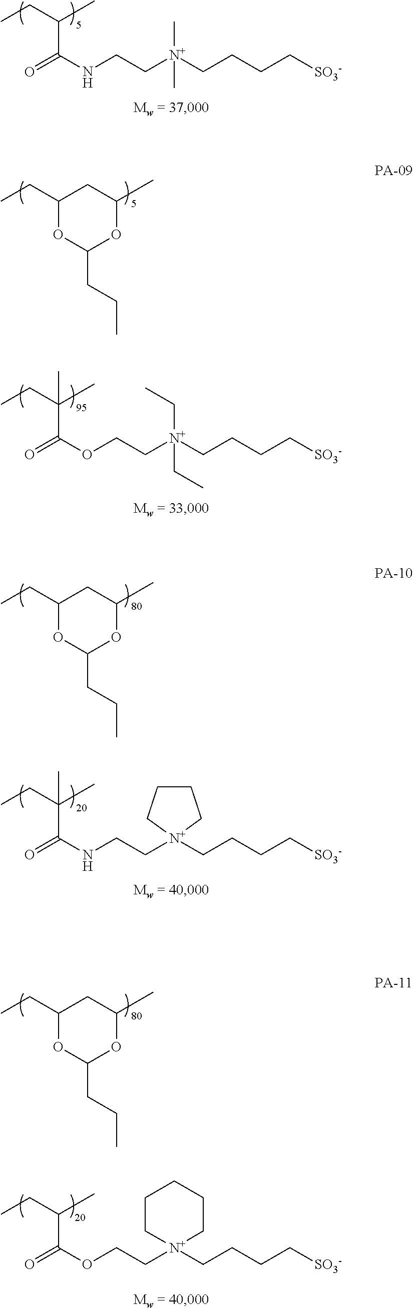

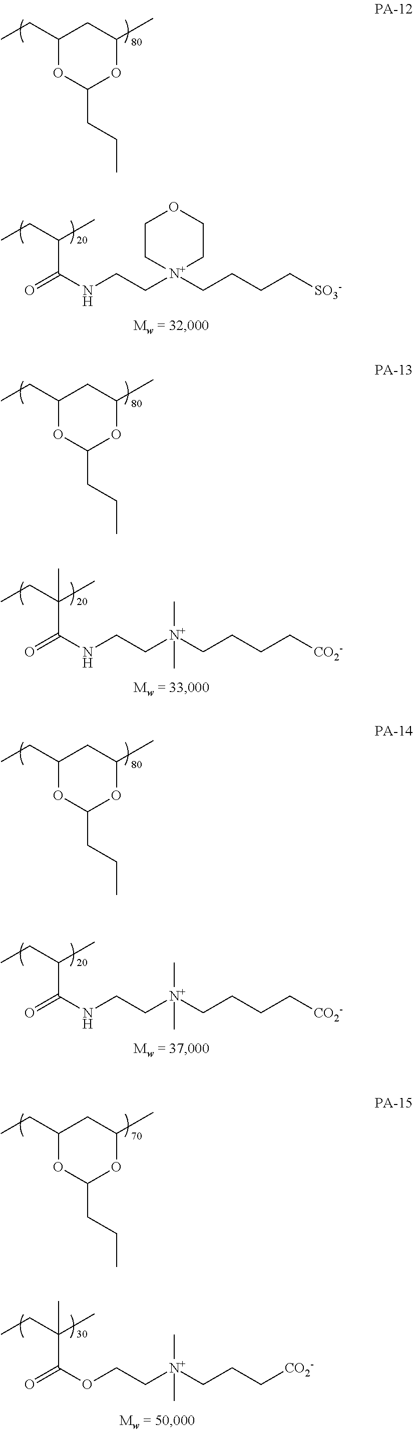

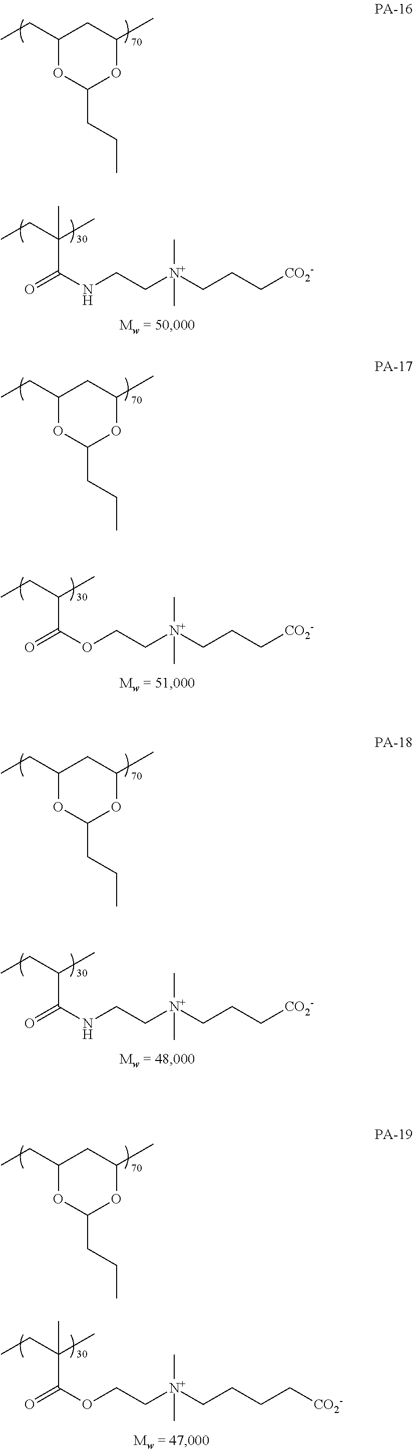

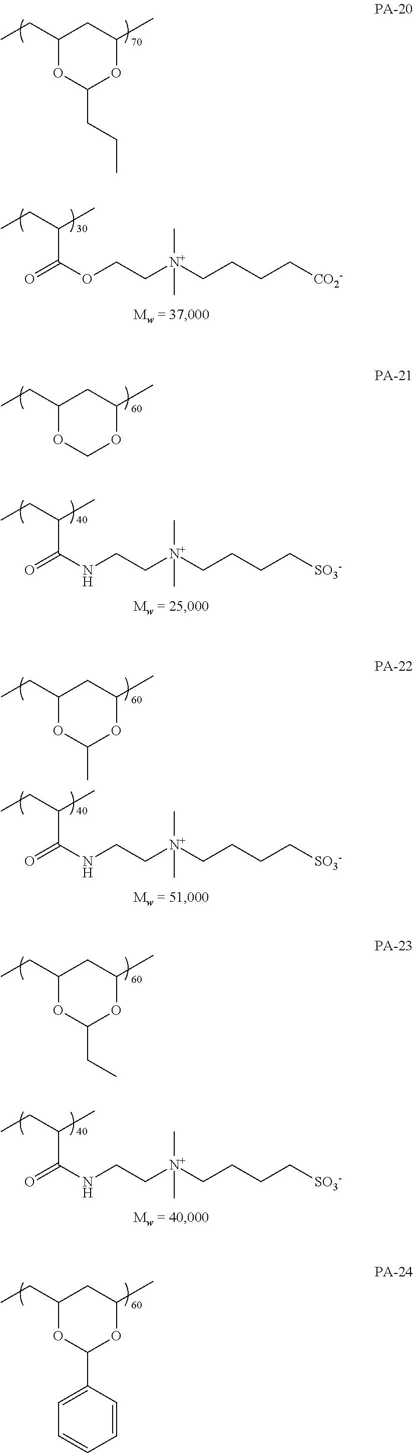

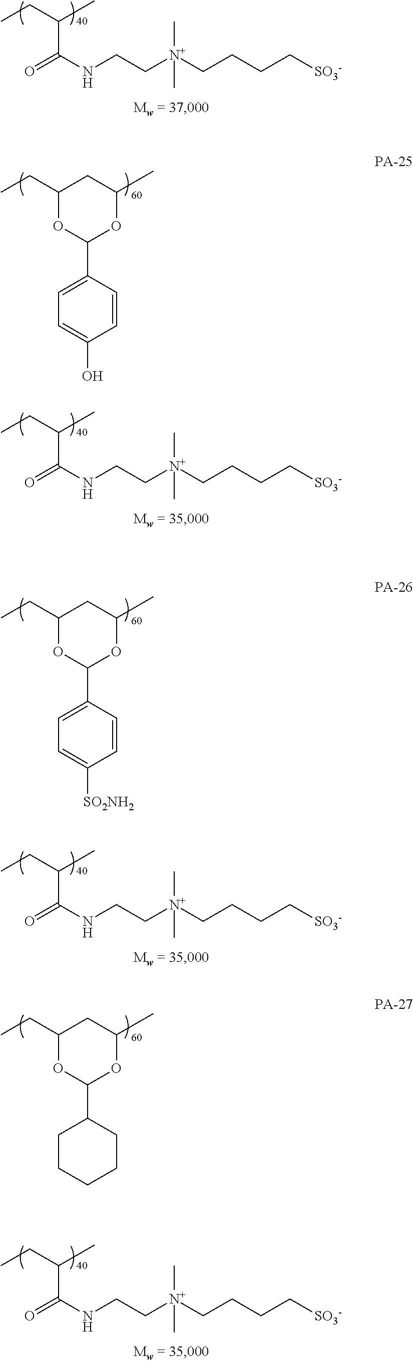

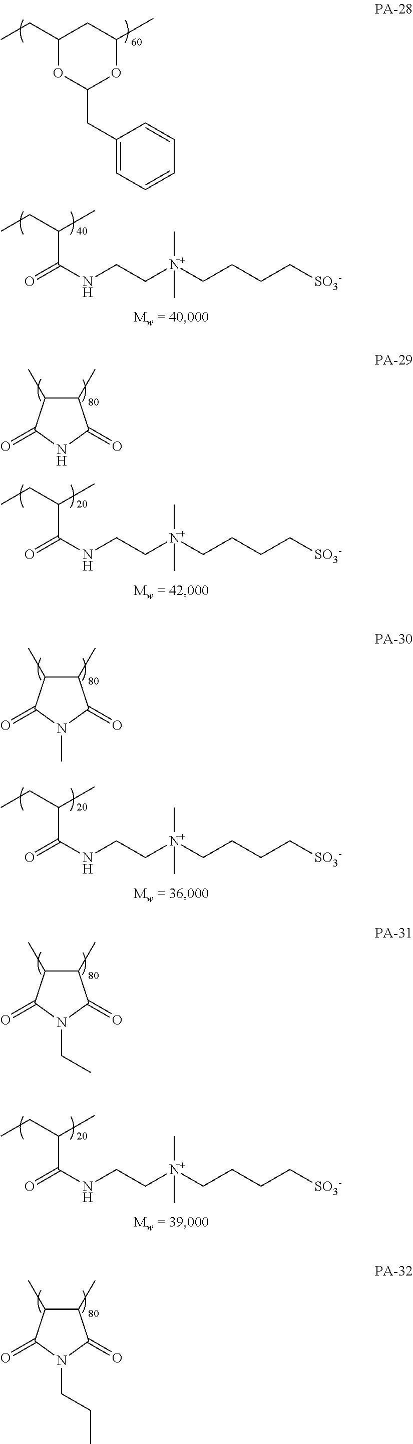

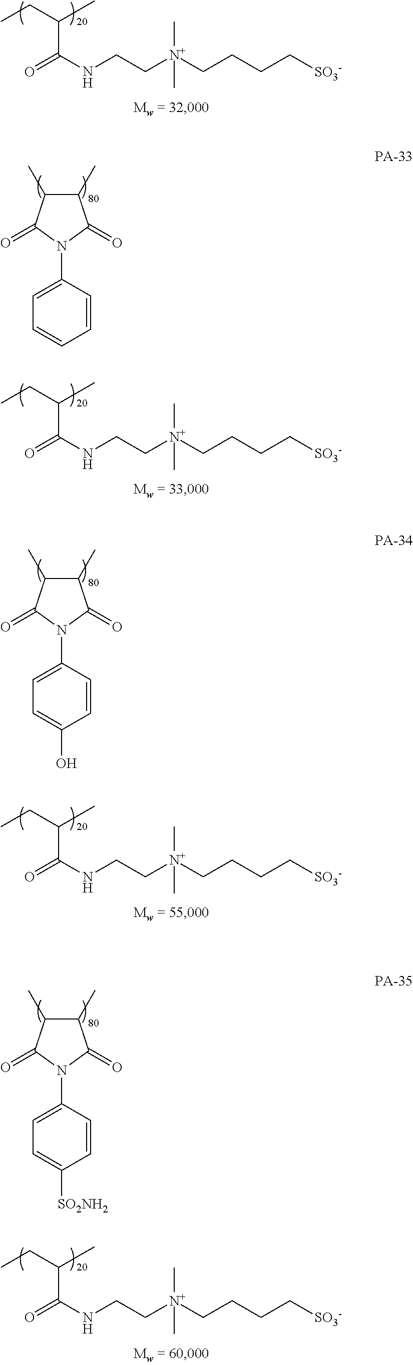

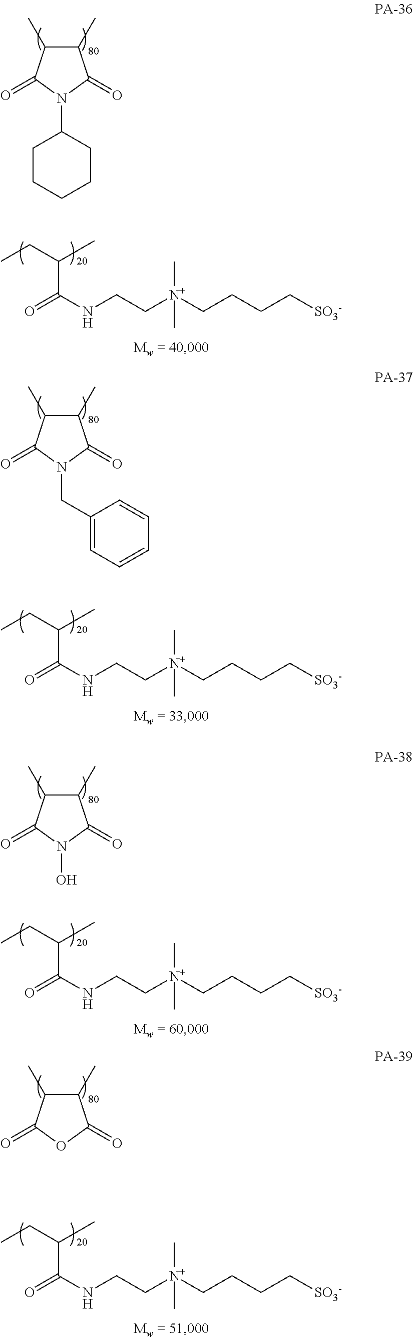

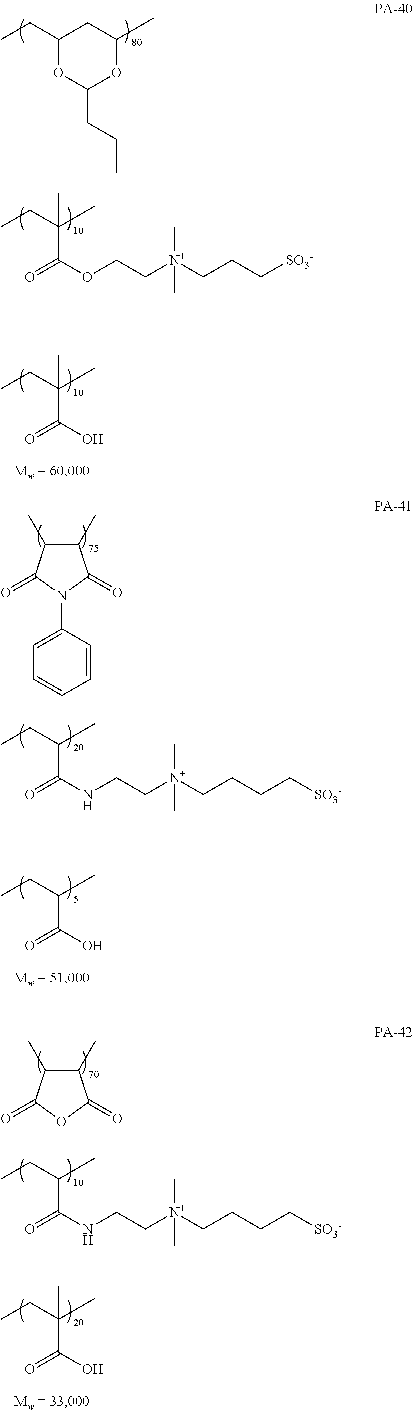

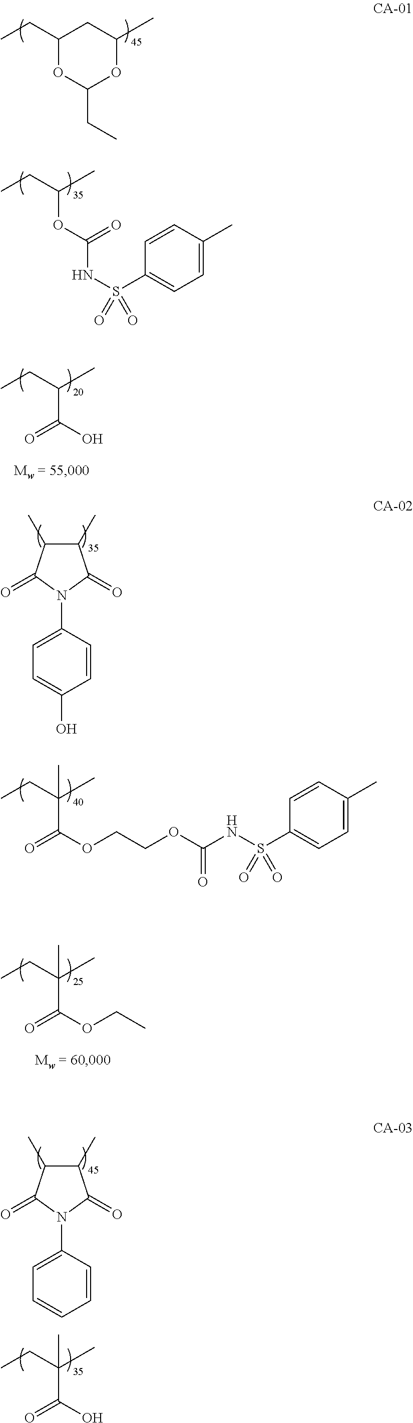

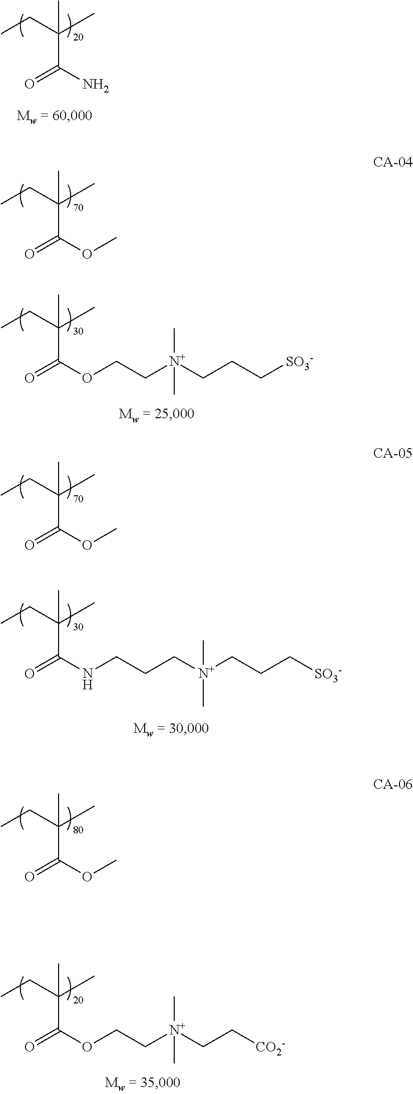

Synthesis of Urethane Binder (PU-01)

In a 1,000-ml three-necked round bottom flask equipped with a condenser and a stirrer, 4,4′-dicyclohexylmethane diisocyanate (262 g) and a compound X-2 mentioned below (241 g) were dissolved in N,N-dimethylacetamide (500 g).

Subsequently, zinc octylate (0.5 g) was added thereto, followed by heating at 80° C. for 8 hours under stirring. Thereafter, the solution was diluted with 200 g of N,N-dimethylacetamide and 20 g of methyl alcohol, thereby obtaining a binder (PU-01). The weight average molecular weight (in terms of polystyrene) thereof measured by GPC was 80,000.

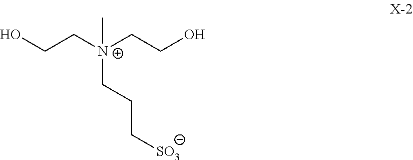

In the same manner as described above, PU-02 to PU-20, CU01, and CU02 were synthesized. The respective structures and the molecular weights are shown below.

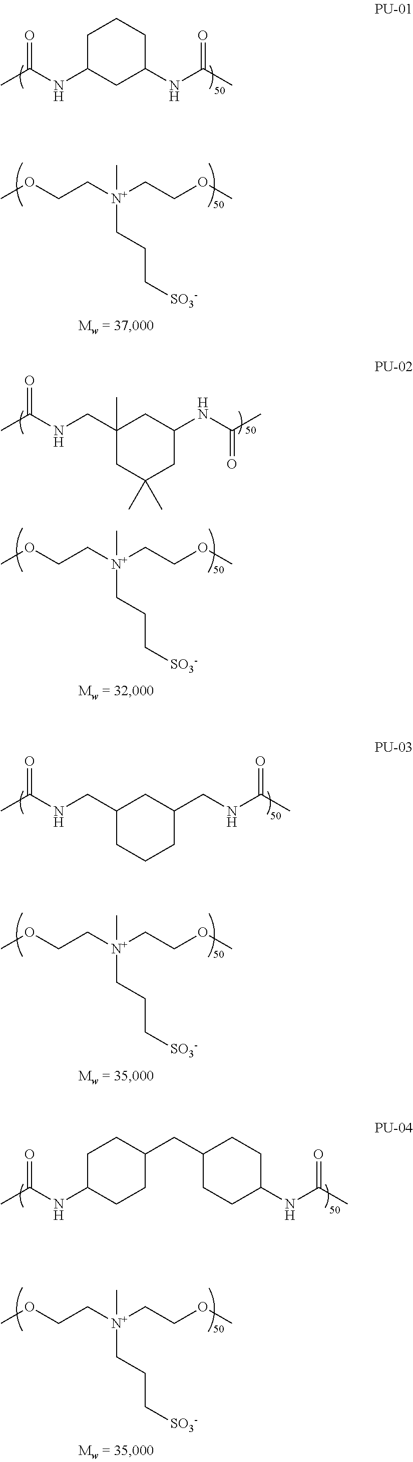

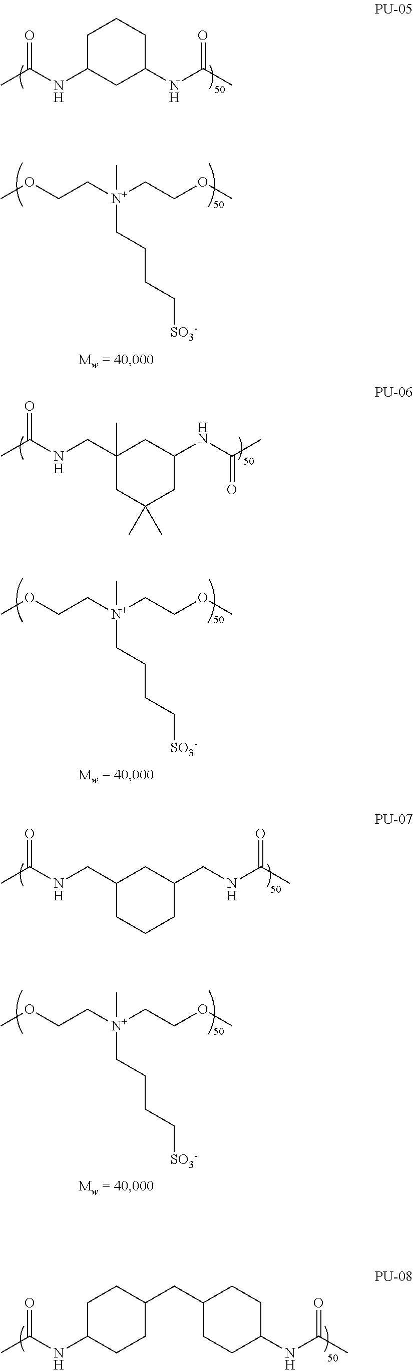

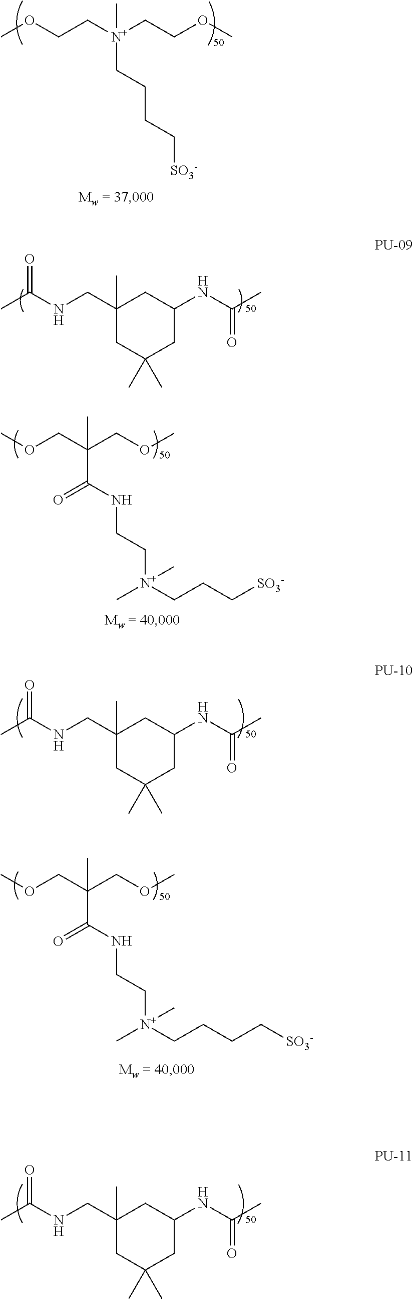

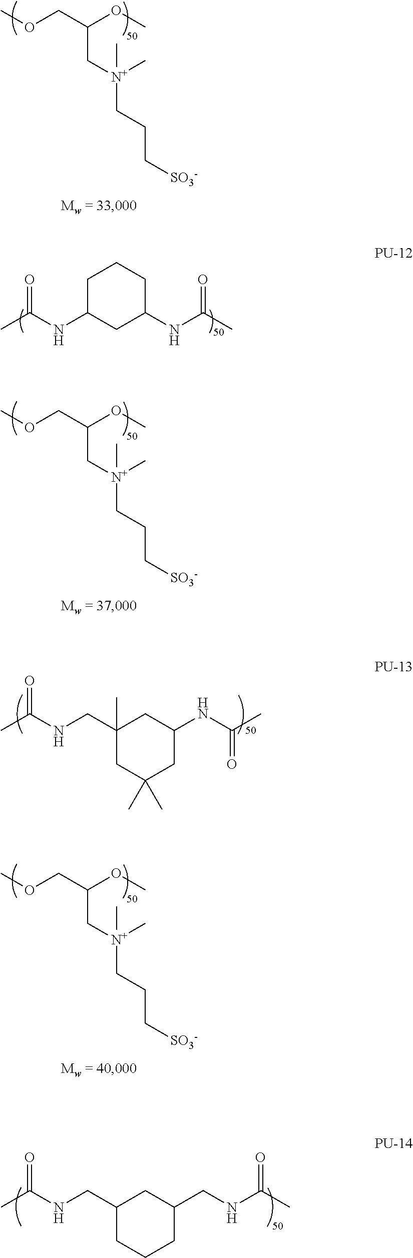

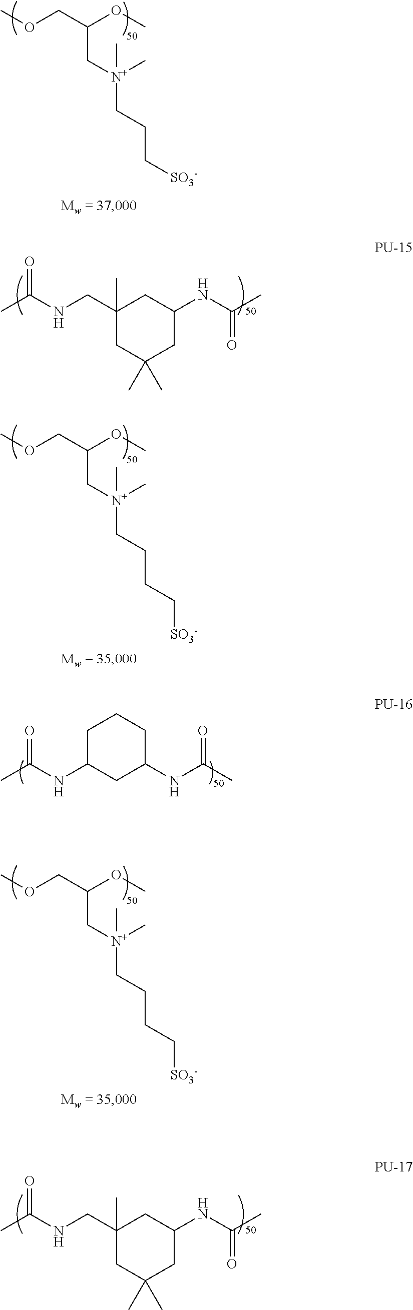

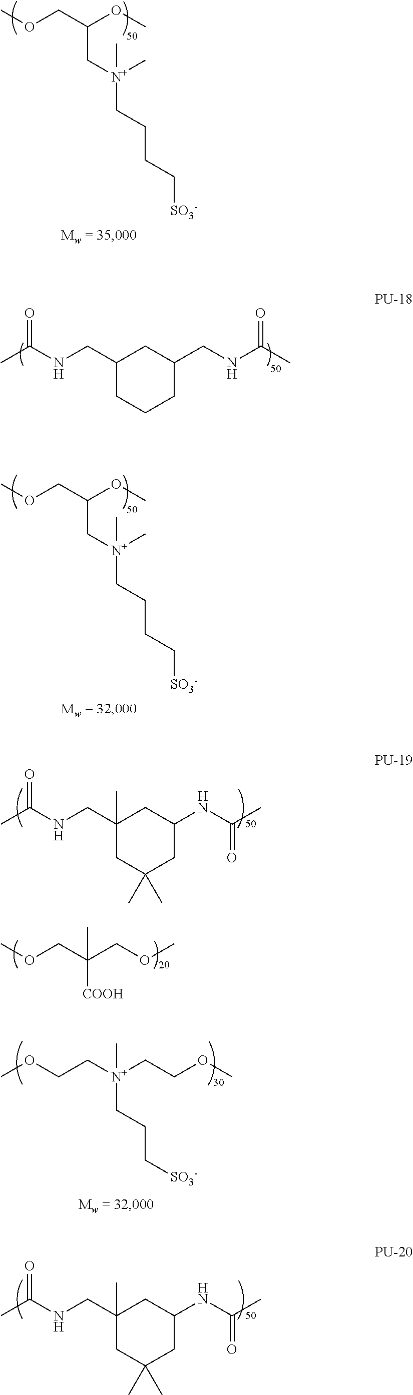

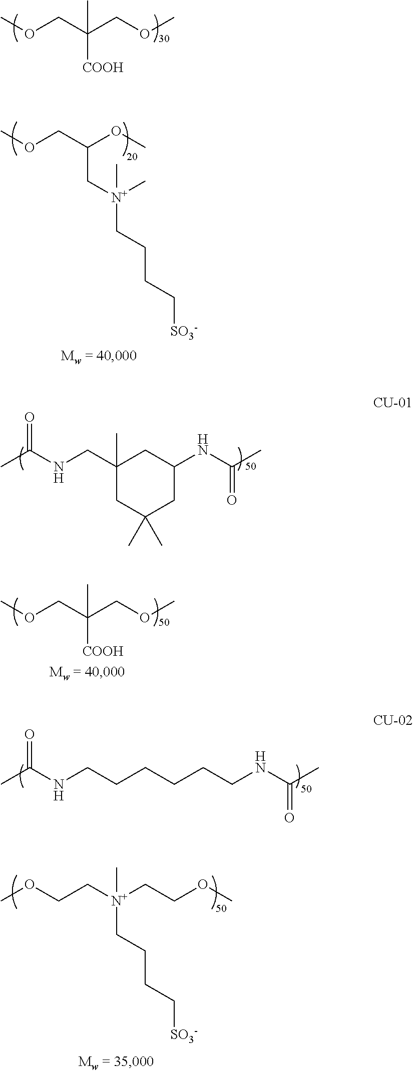

### Examples 1 to 6 and Comparative Examples 1 to 5

### Printing Plate Precursor Having Single Layered Positive-Working Image Recording Layer

### Preparation of Hydrophilic Support

The surface of an aluminum plate of JIS A 1050 was grain-dressed with a rotating nylon brush by using a pumice-water suspension as an abrasive. At this time, the surface roughness (center line average roughness) was 0.5 μm. After washed with water, the aluminum plate was dipped in a 10% aqueous caustic soda solution that had been warmed to 70° C., so that the aluminum plate was etched such that the amount of dissolved aluminum became 6 g/m³. After washed with water, the resultant was neutralized by being dipped in a 30% aqueous nitric acid solution for 1 minute and then washed with water sufficiently. Subsequently, the resultant was subjected to electrolytic surface roughening for 20 seconds in a 0.7% aqueous nitric acid solution by using alternating waveform voltages of square waves of a voltage at the time of an anode of 13 volt and a voltage at the time of a cathode of 6 volt, and the surface was washed by being dipped in a 20% sulfuric acid solution at 50° C., followed by washing with water.

The aluminum plate having undergone the surface roughening was treated in a 20% aqueous sulfuric acid solution so as to form a porous anode oxide film by using direct current. Electrolysis was performed at a current density of 5 A/dm², and the time of electrolysis was adjusted, thereby preparing a substrate having an anode oxide film with a mass of 4.0 g/m² on the surface. This substrate was treated for 10 seconds in a saturated vapor chamber under 1 atmospheric pressure at 100° C., thereby preparing a substrate (a) having a sealing rate of 60%.

The substrate (a) was treated for 10 seconds at 30° C. in a 2.5% by mass aqueous sodium silicate solution so as to hydrophilize the surface, and then the following undercoating liquid was coated thereto. The coating film was dried for 15 seconds at 80° C., thereby obtaining a support [A] for a planographic printing plate. The coating amount of the film after drying was 15 mg/m².

(Undercoat Liquid)

| The following copolymer | 0.3 | g |
|---|---|---|
| (weight average molecular weight: 28,000) | | |
| Methanol | 100 | g |
| Water | 1 | g |

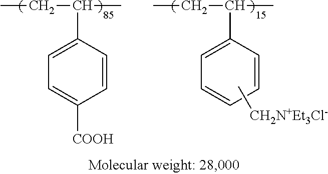

Formation of Image Recording Layer

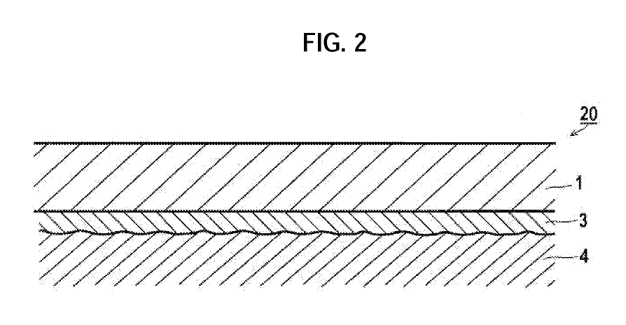

The thus-obtained support [A] having undergone an undercoat was coated with the photosensitive liquid 1 mentioned below, in such a manner that the coating amount of the photosensitive liquid 1 became 1.8 g/m², followed by drying, to thereby form a photosensitive layer (image recording layer). In this manner, a planographic printing plate precursor having a single layer structure as shown in FIG. 2 was obtained.

(Photosensitive Liquid 1)

| Novolac resin (m/p-cresol (6/4); mass average molecular | 1.0 | g |
|---|---|---|
| weight = 7,000; unreacted cresol = 0.5% by mass) | | |
| Copolymer shown in Table 1 | 1.0 | g |
| Cyanine dye A (having the structure shown below ) | 0.1 | g |
| Phthalic anhydride | 0.05 | g |
| p-Toluenesulfonic acid | 0.002 | g |
| Dye in which 6-hydroxy-β-naphthalenesulfonic acid | 0.02 | g |
| acts as a counter ion of ethyl violet | | |
| Fluoropolymer (MEGAFAC F-176 (solid content: 20%), | 0.015 | g |
| product name, manufactured by DIC Corporation) | | |
| Fluoropolymer (MEGAFAC MCF-312 (solid content: 30%), | 0.035 | g |
| product name, manufactured by DIC Corporation) | | |
| Methyl ethyl ketone | 4.0 | g |
| Propylene glycol monomethyl ether (manufactured by | 4.0 | g |
| Nippon Nyukazai Co., Ltd.) | | |
| γ-Butyrolactone | 4.0 | g |

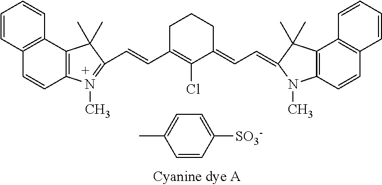

Exposed Portion Developing Time

A test pattern was drawn in the planographic printing plate precursor in the form of an image by using a TRENDSETTER (product name, manufactured by Creo) while changing the exposure energy. Thereafter, the precursor was dipped in a developing bath filled with a developer DT-2 (product name, manufactured by FUJIFILM Corporation) which was diluted to yield a conductivity of 43 mS/cm, while changing time. The dipping time when the image density became the same as the image density of the A1 support was taken as exposed portion developing time.

Evaluation of Printing Durability

A test pattern was drawn in the planographic printing plate precursor in the form of an image at a beam intensity of 9 W and at a drum rotation speed of 150 rpm by using a TRENDSETTER (product name, manufactured by Creo). Thereafter, by using a PS processor-LP940H (trade name, manufactured by FUJI PHOTO FILM Co., Ltd.) charged with a developer DT-2 (product name, manufactured by FUJIFILM Corporation) which was diluted to yield a conductivity of 43 mS/cm, development was performed at a developing temperature of 30° C. for a developing time of 20 seconds. The developing was performed while varying the developing time for evaluating developability. Continuous printing was conducted using a printing machine LITHRONE (product name, manufactured by Komori Corporation). At this time, how many sheets of paper could be printed while maintaining sufficient ink density was counted visually so as to evaluate printing durability. The results are shown in Table 1. As the test pattern, a 2 cm×2 cm solid image (full image portion) was used. The number of sheets until the occurrence of blurring or deletion was observed in the printed portion by the visual evaluation of the printout was taken as a number of sheets of printing completion.

(Developer)

| | | |
|---|---|---|
| D-Sorbitol | 2.5% | by mass |
| Sodium hydroxide | 0.85% | by mass |
| Polyethylene glycol lauryl ether | 0.5% | by mass |
| (mass average molecular weight: 1,000) | | |
| Water | 96.15% | by mass |

Evaluation of Developability

A test pattern was drawn in the obtained photosensitive planographic printing plate precursor in the form of an image at a drum rotation speed of 150 rpm and at a beam intensity of 8 W by using a TRENDSETTER (trade name, manufactured by Creo). Thereafter, by using a PS processor LP-940H (trade name, manufactured by FUJIFILM Corporation), development was performed for a developing time of 12 seconds while keeping the liquid temperature at 30° C., thereby obtaining samples for evaluation. At this time, as a developer, a solution was used which was obtained by blowing carbon dioxide into a solution prepared by mixing a developer DT-2R (trade name, manufactured by FUJIFILM Corporation) with tap water in a ratio of 1:6.5.

As a gum liquid, a liquid was used which was obtained by mixing a gum solution FG-1 (trade name, manufactured by FUJIFILM Corporation) with tap water in a ratio of 1:1 and diluting the mixture. While the conductivity of the developer was changed by an interval of 2 mS/cm from 58 mS/cm to 42 mS/cm, the obtained samples were observed.

First, the color shade and the state of the formed image were visually observed in the image portion, and the highest conductivity at which an excellent image not showing image friction was obtained was indicated as a numerical value.

A higher numerical value indicates a better developability, which means that images were able to be developed even with a highly sensitive developer.

The non-image portion was observed with a loupe, and a conductivity at which a spot-like remaining film started to be found was indicated as a numerical value. In this case, a smaller value indicates a better developability, which means that images were able to be developed even with a low-sensitive developer.

The results are shown in Table 1.

Evaluation of Ablation

A transparent polyethylene terephthalate film (manufactured by FUJIFILM Corporation) having a thickness of 0.1 mm was tightly adhered to the surface of the obtained planographic printing plate precursor. In this state, the entire surface of the precursor was exposed to light at a drum rotation speed of 150 rpm and at a beam intensity of 10 W by using a TRENDSETTER (trade name, manufactured by Creo).

After the light exposure, the polyethylene terephthalate film was removed to visually observe the precursor, thereby observing the contamination level of the surface.

In the evaluation, “A” was given to a precursor not contaminated, “B” was given to a precursor slightly contaminated, and “C” was given to a precursor that was contaminated to such a degree that it was impossible to see the other side through the film, thereby judging the respective precursors.

The results are shown in Table 1.

TABLE 1

| | | | Printing | |
|---|---|---|---|---|
| | (B) | | durability | |
| | Copolymer | Develop- | (Number of | |
| | or | ability | sheets | Ablation |
| | comparative | (Developing | of printing | (Visual |
| | binder | time) | completion) | evaluation) |
| Example 1 | PA-06 | 12 | 180,000 sheets | A |
| Example 2 | PA-08 | 12 | 180,000 sheets | A |
| Example 3 | PA-40 | 10 | 180,000 sheets | A |
| Example 4 | PU-02 | 12 | 170,000 sheets | A |
| Example 5 | PU-06 | 12 | 170,000 sheets | A |
| Example 6 | PU-19 | 10 | 180,000 sheets | A |
| Comparative | CA-01 | 30 | 70,000 sheets | C |
| Example 1 | | | | |
| Comparative | CA-04 | 23 | 40,000 sheets | C |
| Example 2 | | | | |
| Comparative | CA-06 | 27 | 40,000 sheets | C |
| Example 3 | | | | |
| Comparative | CU-01 | 28 | 60,000 sheets | C |
| Example 4 | | | | |
| Comparative | CU-02 | 22 | 20,000 sheets | C |
| Example 5 | | | | |

From Table 1, it is clearly understood that the planographic printing plate precursors having the positive-working image recording layer of examples of the present invention show superior developability, image portion strength, and printing durability, and that the non-image portion is more rapidly removed and the ablation caused at the time of image recording is more effectively inhibited in these precursors, as compared to the planographic printing plate precursors of comparative examples.

### Examples 7 to 68 and Comparative Examples 6 to 13

### Printing Plate Precursors Having Multi-Layered Positive-Working Image Recording Layer

### Preparation of Support

The surface of an aluminum plate of JIS A1050 having a thickness of 0.3 mm was grain-dressed with a rotating nylon brush by using a pumice-water suspension as an abrasive. At this time, the surface roughness (center line average roughness) was 0.5 μm. After washed with water, the aluminum plate was dipped in a 10% aqueous caustic soda solution that had been warmed to 70° C., so that the aluminum plate was etched such that the amount of dissolved aluminum became 6 g/m³. After washed with water, the resultant was neutralized by being dipped in a 30% aqueous nitric acid solution for 1 minute and then washed with water sufficiently. Subsequently, the resultant was subjected to electrolytic surface roughening for 20 seconds in a 0.7% aqueous nitric acid solution by using alternating waveform voltages of square waves of a voltage at the time of an anode of 13 volt and a voltage at the time of a cathode of 6 volt, and the surface was washed by being dipped in a 20% sulfuric acid solution at 50° C., followed by washing with water. The aluminum plate having undergone the surface roughening was treated in a 20% aqueous sulfuric acid solution so as to form a porous anode oxide film by using direct current. Electrolysis was performed at a current density of 5 A/dm², and the time of electrolysis was adjusted, thereby preparing a substrate having an anode oxide film with a mass of 4.0 g/m² on the surface. This substrate was treated for 10 seconds in a saturated vapor chamber under 1 atmospheric pressure at 100° C., thereby preparing a substrate (b) having a sealing rate of 60%. The substrate (b) was treated for 10 seconds at 30° C. in a 2.5% by mass aqueous sodium silicate solution so as to hydrophilize the surface, and then the undercoating liquid 1 mentioned below was coated thereto. The coating film was dried for 15 seconds at 80° C., thereby obtaining a support [B] for a planographic printing plate. The coating amount of the film after drying was 15 mg/m².

Formation of Intermediate Undercoat Layer

The support [B] prepared as above was coated with the following coating liquid 1 for intermediate layer formation, followed by drying at 80° C. for 15 seconds, thereby forming an intermediate layer. The coating amount after drying was 15 mg/m².

(Undercoat Liquid 1)

| | | |
|---|---|---|
| The following copolymer (weight average | 0.5 | g |
| molecular weight: 28,000) | | |
| Methanol | 100 | g |
| Water | 1 | g |

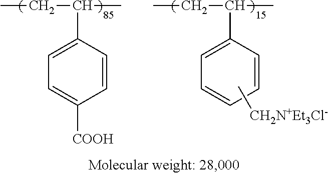

Formation of Image Recording Layer

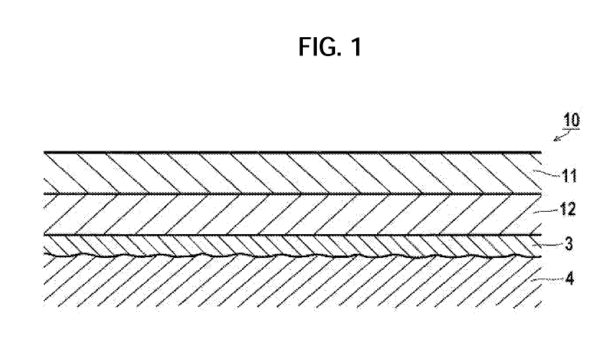

The photosensitive liquid I having the following formulation was coated onto the obtained support [B] having the undercoat layer with a wire bar, and then the resultant was dried for 40 seconds in a drying oven at 150° C. to yield a coating amount of 1.3 g/m², thereby providing a lower layer. After the lower layer was formed, a photosensitive liquid II having the following formulation was coated with a wire bar, thereby providing an upper layer. After the coating, the resultant was dried for 40 seconds at 150° C., thereby obtaining a planographic printing plate precursor in which the total coating amount of the lower and upper layers was 1.7 g/m². This planographic printing plate precursor had a multilayer structure as shown in FIG. 1.

(Photosensitive Liquid I)

| | | |
|---|---|---|
| Copolymer shown in Table 2 | 3.5 | g |
| Dye in which 6-hydroxy-β-naphthalenesulfonic acid | 0.15 | g |
| acts as a counter anion of ethyl violet | | |
| Infrared absorber (the cyanine dye A) | 0.25 | g |
| Bisphenolsulfone | 0.3 | g |
| Tetrahydrophthalic acid | 0.4 | g |
| Fluorosurfactant (MEGAFAC F-780, product name, | 0.02 | g |
| manufactured by DIC Corporation) | | |
| Methyl ethyl ketone | 30 | g |
| Propylene glycol monomethyl ether | 15 | g |
| γ-Butyrolactone | 15 | g |

(Photosensitive Liquid II)

| | |
|---|---|
| Novolac resin (m-cresol/p-cresol/phenol = 3/2/5, Mw 8,000) | 0.68 g |
| Infrared absorber (the cyanine dye A) | 0.045 g |
| Fluorosurfactant (MEGAFAC F-780, product name, | 0.03 g |
| manufactured by DIC Corporation) | |
| Methyl ethyl ketone | 15.0 g |
| 1-Methoxy-2-propanol | 30.0 g |

The obtained printing plate precursors were evaluated in terms of printing durability, developability, and ablation in the same manner as in Example 1. The results are shown in Table 2.

TABLE 2

| | | | Printing | |
|---|---|---|---|---|
| | (B) | | durability | |
| | Copolymer | Develop- | (Number | |
| | or | ability | of sheets | Ablation |
| | comparative | (Developing | of printing | (Visual |
| | binder | time) | completion) | evaluation) |
| Example 7 | PA-01 | 12 | 110,000 sheets | B |
| Example 8 | PA-02 | 10 | 160,000 sheets | B |
| Example 9 | PA-03 | 12 | 150,000 sheets | B |
| Example 10 | PA-04 | 10 | 170,000 sheets | B |
| Example 11 | PA-05 | 10 | 170,000 sheets | B |
| Example 12 | PA-06 | 9 | 200,000 sheets | A |
| Example 13 | PA-07 | 10 | 170,000 sheets | B |
| Example 14 | PA-08 | 9 | 200,000 sheets | A |
| Example 15 | PA-09 | 12 | 110,000 sheets | B |
| Example 16 | PA-10 | 12 | 150,000 sheets | B |
| Example 17 | PA-11 | 12 | 140,000 sheets | B |
| Example 18 | PA-12 | 12 | 150,000 sheets | B |
| Example 19 | PA-13 | 12 | 120,000 sheets | B |
| Example 20 | PA-14 | 12 | 130,000 sheets | B |
| Example 21 | PA-15 | 12 | 140,000 sheets | B |
| Example 22 | PA-16 | 12 | 130,000 sheets | B |
| Example 23 | PA-17 | 12 | 150,000 sheets | B |
| Example 24 | PA-18 | 12 | 130,000 sheets | B |
| Example 25 | PA-19 | 12 | 120,000 sheets | B |
| Example 26 | PA-20 | 12 | 110,000 sheets | B |
| Example 27 | PA-21 | 12 | 140,000 sheets | B |
| Example 28 | PA-22 | 10 | 170,000 sheets | B |
| Example 29 | PA-23 | 10 | 170,000 sheets | B |
| Example 30 | PA-24 | 10 | 160,000 sheets | B |
| Example 31 | PA-25 | 10 | 160,000 sheets | B |
| Example 32 | PA-26 | 10 | 170,000 sheets | B |
| Example 33 | PA-27 | 10 | 170,000 sheets | B |
| Example 34 | PA-28 | 12 | 120,000 sheets | B |
| Example 35 | PA-29 | 12 | 150,000 sheets | B |
| Example 36 | PA-30 | 12 | 140,000 sheets | B |
| Example 37 | PA-31 | 12 | 140,000 sheets | B |
| Example 38 | PA-32 | 12 | 150,000 sheets | B |
| Example 39 | PA-33 | 12 | 130,000 sheets | B |
| Example 40 | PA-34 | 12 | 120,000 sheets | B |
| Example 41 | PA-35 | 12 | 140,000 sheets | B |
| Example 42 | PA-36 | 12 | 150,000 sheets | B |
| Example 43 | PA-37 | 12 | 140,000 sheets | B |
| Example 44 | PA-38 | 12 | 120,000 sheets | B |
| Example 45 | PA-39 | 12 | 150,000 sheets | B |
| Example 46 | PA-40 | 7 | 200,000 sheets | A |
| Example 47 | PA-41 | 10 | 160,000 sheets | B |
| Example 48 | PA-42 | 10 | 160,000 sheets | B |
| Example 49 | PU-01 | 10 | 170,000 sheets | B |
| Example 50 | PU-02 | 9 | 180,000 sheets | A |
| Example 51 | PU-03 | 10 | 160,000 sheets | B |
| Example 52 | PU-04 | 10 | 160,000 sheets | B |
| Example 53 | PU-05 | 10 | 160,000 sheets | B |
| Example 54 | PU-06 | 9 | 180,000 sheets | A |
| Example 55 | PU-07 | 10 | 170,000 sheets | B |
| Example 56 | PU-08 | 10 | 170,000 sheets | B |
| Example 57 | PU-09 | 12 | 130,000 sheets | B |
| Example 58 | PU-10 | 12 | 120,000 sheets | B |
| Example 59 | PU-11 | 12 | 140,000 sheets | B |
| Example 60 | PU-12 | 10 | 170,000 sheets | B |
| Example 61 | PU-13 | 12 | 130,000 sheets | B |
| Example 62 | PU-14 | 12 | 150,000 sheets | B |
| Example 63 | PU-15 | 12 | 130,000 sheets | B |
| Example 64 | PU-16 | 10 | 170,000 sheets | B |
| Example 65 | PU-17 | 12 | 120,000 sheets | B |
| Example 66 | PU-18 | 12 | 150,000 sheets | B |
| Example 67 | PU-19 | 7 | 180,000 sheets | A |
| Example 68 | PU-20 | 10 | 170,000 sheets | B |
| Comparative | CA-01 | 22 | 90,000 sheets | C |
| Example 6 | | | | |
| Comparative | CA-02 | 21 | 80,000 sheets | C |
| Example 7 | | | | |
| Comparative | CA-03 | 24 | 80,000 sheets | C |
| Example 8 | | | | |
| Comparative | CA-04 | 17 | 50,000 sheets | C |
| Example 9 | | | | |
| Comparative | CA-05 | 17 | 40,000 sheets | C |
| Example 10 | | | | |
| Comparative | CA-06 | 20 | 40,000 sheets | C |
| Example 11 | | | | |
| Comparative | CU-01 | 21 | 80,000 sheets | C |
| Example 12 | | | | |
| Comparative | CU-02 | 16 | 30,000 sheets | C |
| Example 13 | | | | |

From Table 2, it is clearly understood that the planographic printing plate precursors of examples according to the present invention show excellent developability, image portion strength, and printing durability, and that the non-image portion is rapidly removed and the ablation caused at the time of image recording is effectively inhibited in these precursors, similarly to the cases of the precursors having a single-layered positive-working image recording layer, even when the precursors had the embodiment in which the precursors have the multi-layered positive-working image recording layer and contain the (B) copolymer according to the present invention in the lower layer thereof.

### Examples 69 to 74 and Comparative Examples 14 to 18

### Printing Plate Precursors Having Multi-Layered Positive-Working Image Recording Layer

A Support was prepared in the same manner as in Example 68.

### Formation of Intermediate Undercoat Layer

An intermediate undercoat layer was prepared in the same manner as in Example 68, except that the undercoating liquid 1 was changed to the following undercoating liquid 2.

(Undercoating Liquid 2)

| The following copolymer (weight | 0.3 | g |
|---|---|---|
| average molecular weight: 31,000) | | |
| Methanol | 100 | g |
| Water | 1 | g |

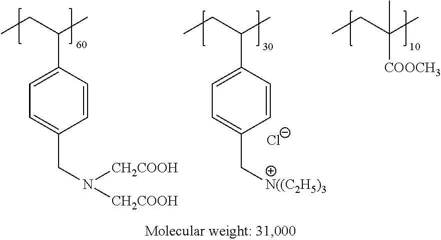

Formation of Image Recording Layer

A photosensitive liquid III having the following formulation was coated onto the obtained support having undergone undercoating with a wire bar, and then the resultant was dried for 40 seconds in a drying oven at 150° C. to yield a coating amount of 1.3 g/m², thereby forming a lower layer. After the lower layer was formed, a photosensitive liquid IV having the following formulation was coated with a wire bar, thereby providing an upper layer. After the coating, the resultant was dried for 40 seconds at 150° C., thereby obtaining a planographic printing plate precursor in which the total coating amount of the lower and upper layers was 1.7 g/m². This planographic printing plate precursor had a multilayer structure as shown in FIG. 1.

(Photosensitive Liquid III)

| | | |
|---|---|---|
| The following polymer (Ref-1) | 3.5 | g |
| Dye in which 6-hydroxy-β-naphthalenesulfonic acid acts as a counter anion of ethyl violet | 0.15 | g |
| m,p-Cresol novolac (m/p ratio = 6/4, mass average molecular weight: 6,000) | 0.6 | g |
| Infrared absorber (the cyanine dye A) | 0.25 | g |
| Bisphenolsulfone | 0.3 | g |
| Tetrahydrophthalic acid | 0.4 | g |
| Fluorosurfactant (MEGAFAC F-780, product name, manufactured by DIC Corporation) | 0.02 | g |
| Methyl ethyl ketone | 30 | g |
| Propylene glycol monomethyl ether | 15 | g |
| γ-Butyrolactone | 15 | g |

| | | |
|---|---|---|
| Ref-1 M_{w} = 55,000 | 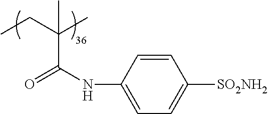 | 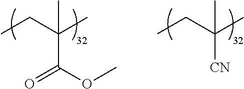 |

(Photosensitive Liquid IV)

| | |
|---|---|
| Novolac resin (m-cresol/p-cresol/phenol = 3/2/5, Mw 8,000) | 0.68 g |
| Copolymer described in Table 3 | 0.20 g |
| Infrared absorber (the cyanine dye A) | 0.045 g |
| Fluorosurfactant (MEGAFAC F-780, product name, | 0.03 g |
| manufactured by DIC Corporation) | |
| Methyl ethyl ketone | 15.0 g |
| 1-Methoxy-2-propanol | 30.0 g |

Printing durability, developability, and ablation were evaluated in the same manner as in Example 1. The results are shown in Table 3.

TABLE 3

| | | | Printing | |
|---|---|---|---|---|
| | (B) | | durability | |
| | Copolymer | Develop- | (Number of | |
| | or | ability | sheets | Ablation |
| | comparative | (Developing | of printing | (Visual |
| | binder | time) | completion) | evaluation) |
| Example 69 | PA-06 | 9 | 200,000 sheets | A |
| Example 70 | PA-08 | 9 | 200,000 sheets | A |
| Example 71 | PA-40 | 7 | 200,000 sheets | A |
| Example 72 | PU-02 | 9 | 180,000 sheets | A |
| Example 73 | PU-06 | 9 | 180,000 sheets | A |
| Example 74 | PU-19 | 7 | 180,000 sheets | A |
| Comparative | CA-01 | 22 | 40,000 sheets | C |
| Example 14 | | | | |
| Comparative | CA-04 | 17 | 30,000 sheets | C |
| Example 15 | | | | |
| Comparative | CA-06 | 20 | 20,000 sheets | C |
| Example 16 | | | | |
| Comparative | CU-01 | 21 | 20,000 sheets | C |
| Example 17 | | | | |
| Comparative | CU-02 | 16 | 30,000 sheets | C |
| Example 18 | | | | |

From Table 3, it is clearly understood that the planographic printing plate precursors of examples having the multi-layered positive-working image recording layer according to the present invention show excellent developability, image portion strength, and printing durability, and that the non-image portion is rapidly removed and the ablation caused at the time of image recording is effectively inhibited in these precursors, even when the precursors take the embodiment in which the precursors contain the (B) copolymer according to the present invention in the upper layer of the image recording layer.

### Examples 75 to 80 and Comparative Examples 19 to 23

### Printing Plate Precursors Having Multi-Layered Positive-Working Image Recording Layer

### Preparation of Support

### Formation of Intermediate Undercoat Layer

A Support and an intermediate undercoat layer were prepared in the same manner as in Example 1.

### Preparation of Image Recording Layer

A photosensitive liquid V having the following formulation was coated onto the obtained support having undergone undercoating with a wire bar, and then the resultant was dried for 40 seconds in a drying oven at 150° C. to yield a coating amount of 1.2 g/m², thereby forming a lower layer. After the lower layer was formed, a photosensitive liquid VI having the following formulation was coated with a wire bar, thereby providing an upper layer. After the coating, the resultant was dried for 40 seconds at 150° C., thereby obtaining a planographic printing plate precursor in which the total coating amount of the lower and upper layers was 1.6 g/m². This planographic printing plate precursor had a multilayer structure as shown in FIG. 1.

(Photosensitive Liquid V)

| | | |
|---|---|---|
| The copolymer shown in Table 4 | 3.5 | g |
| Dye in which 6-hydroxy-β-naphthalenesulfonic acid acts as | 0.15 | g |
| a counter anion of ethyl violet | | |
| m,p-Cresol novolac (m/p ratio = 6/4, mass average | 0.6 | g |
| molecular weight of 6,000) | | |
| Infrared absorber (the cyanine dye A) | 0.25 | g |
| Bisphenolsulfone | 0.3 | g |
| Tetrahydrophthalic acid | 0.4 | g |
| Fluorosurfactant (MEGAFAC F-780, product name, | 0.02 | g |
| manufactured by DIC Corporation) | | |
| Methyl ethyl ketone | 30 | g |
| Propylene glycol monomethyl ether | 15 | g |
| γ-Butyrolactone | 15 | g |

(Photosensitive Liquid VI)

| Novolac resin (m-cresol/p-cresol/phenol = 3/2/5, Mw 8,000) | 0.68 | g |
|---|---|---|
| The polymer shown below (Ref-2) | 0.15 | g |
| Infrared absorber (the cyanine dye A) | 0.045 | g |
| Fluorosurfactant (MEGAFAC F-780, product name, | 0.03 | g |
| manufactured by DIC Corporation) | | |
| Methyl ethyl ketone | 15.0 | g |
| 1-Methoxy-2-propanol | 30.0 | g |

| | |
|---|---|
| 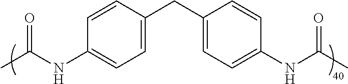 | 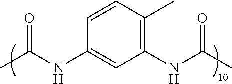 |

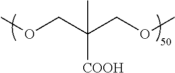

Ref-2
M_{w} = 28,000

Exposed Portion Developing Time

Exposed portion developing time was evaluated in the same manner as in Example 1, except that the developer 2 mentioned below was used as a developer.

### Evaluation of Printing Durability

Printing durability was evaluated in the same manner as in Example 1, except that images were developed in the following development step using the following developer 2 as a developer. The results are shown in Table 4.

### Development Step

The planographic printing plate precursors after the light exposure were subjected to developing at 30° C. by using a commercially-available automatic developing processor and the following developer 2. The developing processor had a developing bath of 25 L, and operated at a plate transport speed of 100 cm/min, with a rotation of one brush roll (outer size of 50 mm) to which polybutylene terephthalate fiber (a strand diameter of 200 μm, a strand length of 17 mm) has been implanted at 200 revolutions per minute (a circumferential speed of the leading end of the brush of 0.52 m/sec) in the same direction as the transport direction, and at a drying temperature of 80° C.

(Developer 2)

| | | |
|---|---|---|
| Water | 8963.8 | g |
| Sodium carbonate | 200 | g |
| Sodium hydrogen carbonate | 100 | g |
| NEWCOL B4SN (trade name, a polyoxyethylene | 300 | g |
| naphthyl ether sulfuric acid salt manufactured by | | |
| Nippon Nyukazai Co., Ltd.) | | |
| EDTA 4Na | 80 | g |
| 2-Bromo-2-nitropropanediol | 0.1 | g |
| 2-Methyl-4-isothiazolin-3-one (pH = 9.7) | 0.1 | g |

Evaluation of Developability and Ablation

Developability and ablation of the obtained planographic printing plates were evaluated in the same manner as in Example 1. The results are shown in Table 4.

TABLE 4

| | | | Printing | |
|---|---|---|---|---|
| | (B) | | durability | |
| | Copolymer | Develop- | (Number of | |
| | or | ability | sheets | Ablation |
| | comparative | (Developing | of printing | (Visual |
| | binder | time) | completion) | evaluation) |
| Example 75 | PA-06 | 11 | 200,000 sheets | A |
| Example 76 | PA-08 | 11 | 200,000 sheets | A |
| Example 77 | PA-40 | 11 | 200,000 sheets | A |
| Example 78 | PU-02 | 11 | 180,000 sheets | A |
| Example 79 | PU-06 | 11 | 180,000 sheets | A |
| Example 80 | PU-19 | 11 | 180,000 sheets | A |
| Comparative | CA-01 | 23 | 40,000 sheets | C |
| Example 19 | | | | |
| Comparative | CA-04 | 21 | 40,000 sheets | C |
| Example 20 | | | | |
| Comparative | CA-06 | 22 | 60,000 sheets | C |
| Example 21 | | | | |
| Comparative | CU-01 | 24 | 20,000 sheets | C |
| Example 22 | | | | |
| Comparative | CU-02 | 22 | 20,000 sheets | C |
| Example 23 | | | | |

From Table 4, it is clearly understood that the planographic printing plate precursors of examples having the multi-layered positive-working image recording layer according to the present invention show excellent developability, image portion strength, and printing durability, and that the non-image portion is rapidly removed and the ablation caused at the time of image recording is effectively inhibited in these precursors, even when the image recording layer and the formulation of the developer are changed.

### Examples 81 to 104 and Comparative Examples 24 to 29

### Planographic Printing Plates Having Negative-Working Image Recording Layer

### Preparation of Support

An aluminum plate of JIS A1050 having a thickness of 0.30 mm and a width of 1,030 mm was surface-treated in the following manner.

### Surface Treatment

For the surface treatment, the following treatments (a) to (f) were continuously performed. In addition, after the respective treatments and washing, liquid was drained using a nip roller.

(a) An etching treatment was performed on an aluminum plate in a caustic soda concentration of 26% by mass and an aluminum ion concentration of 6.5% by mass at 70° C., thereby dissolving the aluminum plate at 5 g/m². Then the aluminum plate was washed with water.

(b) A desmutting treatment was performed by spraying an aqueous solution (containing 0.5% by mass of aluminum ions) of a nitric acid concentration of 1% by mass at 30° C., followed by washing with water.

(c) An electrochemical surface roughening treatment was continuously performed using a 60 Hz AC voltage. An electrolytic solution used at this time was a 1% by mass aqueous nitric acid solution (containing 0.5% by mass of aluminum ions and 0.007% by mass of ammonium ions), and the temperature was 30° C. As the AC voltage, a trapezoidal square wave voltage in which a time TP taken for a current value to reach a peak from zero was 2 msec and a duty ratio was 1:1 was used, and a carbon electrode was used as a counter electrode, whereby the electrochemical surface roughening treatment was performed. Ferrite was used for an auxiliary anode. The current density expressed as a peak value of the current was 25 A/dm², and the quantity of electricity expressed as the sum of the quantity of electricity yielded when the aluminum plate was an anode was 250 C/cm². 5% of the current flowing from a power supply was shunted to the auxiliary anode. Thereafter, the resultant was washed with water.

(d) Etching was performed by spraying on an aluminum plate in a caustic soda concentration of 26% by mass and an aluminum ion concentration of 6.5% by mass at 35° C., thereby dissolving the aluminum plate at 0.2 g/m². Thereafter, smut components that contained aluminum hydroxide as a main component generated during the electrochemical surface roughening performed using the AC voltage were removed, and the edge portion of the generated pit was dissolved, thereby smoothening the edge portion. Subsequently, the resultant was washed with water.

(e) A desmutting treatment was performed by spraying an aqueous solution (containing 0.5% by mass of aluminum ions) of a nitric acid concentration of 25% by mass at 60° C., followed by washing with water spraying.

(f) The resultant was subjected to an anodization treatment for 50 seconds in a nitric acid concentration of 170 g/L (containing 0.5% by mass of aluminum ions) at 33° C. and at a current density of 5 A/dm², followed by washing with water. At this time, the weight of the anode oxide film was 2.7 g/m².

The surface roughness Ra of the aluminum supporter obtained in this manner was 0.27 (measurement instrument; SURFCOM, trade name, manufactured by Tokyo Seimitsu Co., Ltd., a leading end diameter of a stylus of 2 μm).

Formation of Undercoat Layer

Thereafter, the following coating liquid for an undercoat layer was coated onto the aluminum support with a wire bar, followed by drying at 90° C. for 30 seconds. The coating amount was 10 mg/m².

(Coating Liquid for Undercoat Layer)

| | | |
|---|---|---|
| Polymer compound A having the following structure | 0.05 | g |
| (weight average molecular weight: 28,000) | | |
| Methanol | 27 | g |
| Ion exchange water | 3 | g |
| Polymer compound A | | |

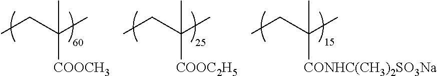

Formation of Image Recording Layer

Subsequently, the following coating liquid [P-1] for a photosensitive layer was prepared and coated on the aluminum support using a wire bar. The resultant was dried at 115° C. for 34 seconds by a hot air drier, thereby obtaining a planographic printing plate precursor. The coating amount after drying was 1.4 g/m².

(Coating Liquid [P-1] for Photosensitive Layer)

| | | |
|---|---|---|
| Phosphonium compound (A-6) | 0.077 | g |
| Infrared absorber (IR-1) | 0.074 | g |
| Polymerization initiator (OS-12) | 0.280 | g |
| Additive (PM-1) | 0.151 | g |
| Polymerizable compound (AM-1) | 1.00 | g |
| Copolymer shown in Table 5 | 1.00 | g |
| Ethyl violet (C-1) | 0.04 | g |
| Fluorosurfactant (MEGAFAC F-780-F, DIC Corporation, | 0.015 | g |
| 30% by mass methyl isobutyl ketone (MIBK) solution) | | |
| Methyl ethyl ketone | 10.4 | g |
| Methanol | 4.83 | g |
| 1-Methoxy-2-propanol | 10.4 | g |

The structures of the phosphonium compound (A-6), the polymerization initiator (OS-12), the infrared absorber (IR-1), the additive (PM-1), the polymerizable compound (AM-1), and the ethyl violet (C-1) that were used for the coating liquid for a photosensitive layer are shown below.

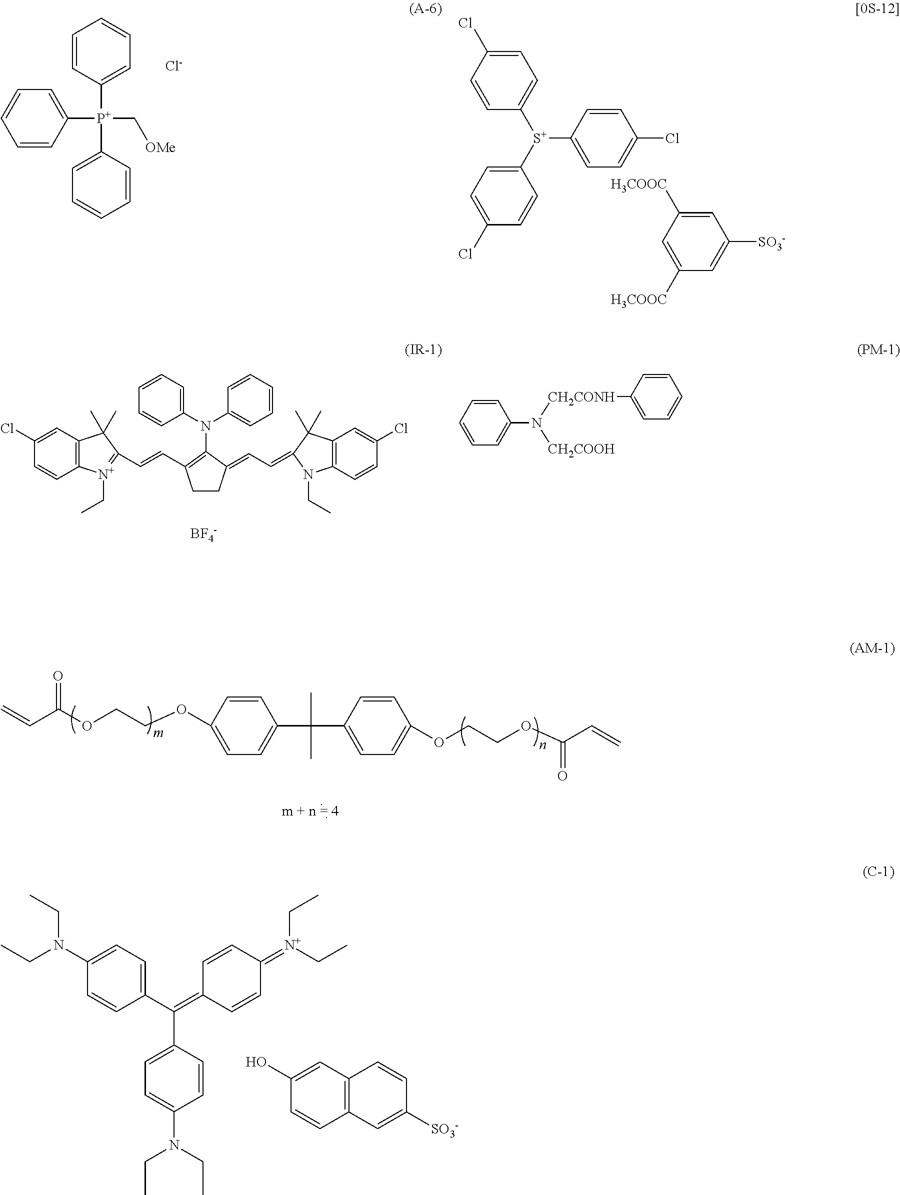

Protective Layer

A 3% by mass aqueous polyvinyl alcohol (a saponification degree of 98 mol %, a polymerization degree of 550) solution was coated onto the surface of the photosensitive layer (image recording layer) such that a dried coating mass became 1.6 g/m², followed by drying at 100° C. for 2 minutes, thereby obtaining a planographic printing plate precursor.

### Evaluation

The obtained planographic printing plate precursor was exposed to light using a TRENDSETTER 800 IIQUANTUM (trade name, manufactured by Creo), at a resolution of 2400 dpi and a rotational frequency of an outer surface drum of 200 rpm, and with an output in a range of from 0 to 8 W, while changing the light amount by 0.15 log E. The exposure was performed under conditions of 25° C. and 50% RH. After the light exposure, a development treatment was performed at a transport speed (line speed) of 2 m/min and a developing temperature of 30° C. by using an automatic developing machine LP-1310HII (trade name, manufactured by FUJIFILM Corporation), without performing heating and washing treatments. A solution of DH-N diluted with water in a ratio of 1:4 was used as a developer, a solution of FCT-421 diluted with water in a ratio of 1:1.4 was used as a developer replenisher, and a solution of GN-2K (trade name, manufactured by FUJIFILM Corporation) diluted with water in a ratio of 1:1 was used as a finisher.

### Printing Durability

Printing was performed as described above by using the obtained planographic printing plate precursor. Printing durability was evaluated based on the number of printed sheets at the time when the ink density (reflection density) in a print sheet of a 7 W exposed portion was lowered by 0.1 compared to the starting point of the printing. The results are shown in Table 5.

### Developability

Using the obtained planographic printing plate precursor, a printing plate was produced as described above while changing the transport speed of the automatic developing machine, and the cyan density in the non-image portion was measured by a Macbeth densitometer. Developability was evaluated by determining a transport speed (m/min) at which the cyan density of the non-image portion became the same as the cyan density of the aluminum substrate. The results are shown in Table 5.

### Ablation

The obtained planographic printing plate precursor was evaluated in terms of ablation in the same manner as in Example 1. The results are shown in table 5.

TABLE 5

| | (B) co- | | | |
|---|---|---|---|---|
| | polymer | Develop- | | |
| | or com- | ability | Printing durability | Ablation |
| | parative | (Transport | (Number of sheets of | (Visual |
| | binder | speed) | printing completion) | evaluation) |
| Example 81 | PA-02 | 120 | 70,000 sheets | B |
| Example 82 | PA-04 | 115 | 80,000 sheets | B |
| Example 83 | PA-05 | 120 | 80,000 sheets | B |
| Example 84 | PA-06 | 150 | 100,000 sheets | A |
| Example 85 | PA-07 | 115 | 70,000 sheets | B |
| Example 86 | PA-08 | 150 | 100,000 sheets | A |
| Example 87 | PA-09 | 105 | 50,000 sheets | B |
| Example 88 | PA-22 | 120 | 70,000 sheets | B |
| Example 89 | PA-28 | 105 | 50,000 sheets | B |
| Example 90 | PA-40 | 160 | 100,000 sheets | A |
| Example 91 | PA-41 | 125 | 80,000 sheets | B |
| Example 92 | PA-42 | 125 | 80,000 sheets | B |
| Example 93 | PU-01 | 115 | 70,000 sheets | B |
| Example 94 | PU-02 | 150 | 90,000 sheets | A |
| Example 95 | PU-03 | 115 | 80,000 sheets | B |
| Example 96 | PU-04 | 115 | 80,000 sheets | B |
| Example 97 | PU-05 | 120 | 80,000 sheets | B |
| Example 98 | PU-06 | 150 | 90,000 sheets | A |
| Example 99 | PU-07 | 120 | 70,000 sheets | B |
| Example 100 | PU-08 | 120 | 70,000 sheets | B |
| Example 101 | PU-09 | 105 | 50,000 sheets | B |
| Example 102 | PU-12 | 115 | 70,000 sheets | B |
| Example 103 | PU-19 | 160 | 90,000 sheets | A |
| Example 104 | PU-20 | 125 | 80,000 sheets | B |
| Comparative | CA-01 | 95 | 40,000 sheets | C |
| Example 24 | | | | |
| Comparative | CA-03 | 90 | 30,000 sheets | C |
| Example 25 | | | | |
| Comparative | CA-04 | 95 | 20,000 sheets | C |
| Example 26 | | | | |
| Comparative | CA-06 | 85 | 20,000 sheets | C |
| Example 27 | | | | |
| Comparative | CU-01 | 85 | 40,000 sheets | C |
| Example 28 | | | | |
| Comparative | CU-02 | 95 | 10,000 sheets | C |
| Example 29 | | | | |

From Table 5, it is clearly understood that the planographic printing plate precursors of examples according to the present invention show excellent developability, and that the non-image portion is rapidly removed, so the developing treatment is effectively performed, even when the precursors have a negative-working image recording layer. It is also clearly understood that the obtained image portion strength is excellent, the printing durability is superior compared to comparative examples, and that the ablation at the time of image recording is effectively inhibited.

This application claims priority under 35 USC 119 from Japanese Patent Application No. 2011-162628 filed on Jul. 25, 2011, the disclosure of which is incorporated by reference herein.

All publications, patent applications, and technical standards mentioned in this specification are herein incorporated by reference to the same extent as if each individual publication, patent application, or technical standard was specifically and individually indicated to be incorporated by reference.

What is claimed is:

1. A photosensitive planographic printing plate precursor, comprising:
a hydrophilic support; and
an image recording layer on the hydrophilic support, the image recording layer comprising:
(A) an infrared absorber; and
(B) a copolymer comprising a repeating unit having a zwitterionic structure in a side chain thereof, and either a repeating unit having a heteroalicyclic structure in a main chain thereof or a repeating unit having a hetero atom and an alicyclic structure in a main chain thereof.

2. The photosensitive planographic printing plate precursor according to claim 1, wherein the heteroalicyclic structure is an acetal structure or a maleimide structure.

3. The photosensitive planographic printing plate precursor according to claim 1, wherein the repeating unit having a heteroalicyclic structure in a main chain thereof comprises a repeating unit represented by the following Formula (I) or (II): 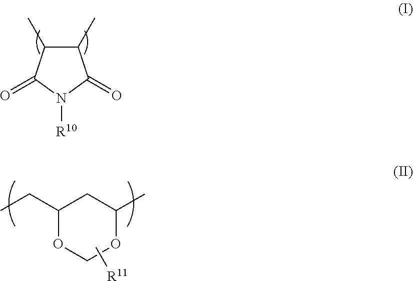
wherein, in Formula (I) and (II), each of R¹⁰ and R¹¹ independently represents a hydrogen atom or a monovalent organic group.

4. The photosensitive planographic printing plate precursor according to claim 3, wherein the monovalent organic group represented by R¹⁰ or R¹¹ is selected from the group consisting of an alkyl group having 1 to 8 carbon atoms, an aryl group having 6 to 10 carbon atoms, a hydroxyl group, and a SO₂NH₂ group.

5. The photosensitive planographic printing plate precursor according to claim 1, wherein the repeating unit having a hetero atom and an alicyclic structure in a main chain thereof comprises a repeating unit represented by the following Formula (IV): 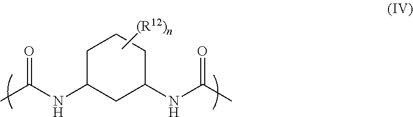
wherein, in Formula (IV), R¹² represents a hydrogen atom or a monovalent organic group; n represents an integer of 1 to 4; and when n represents an integer of 2 to 4, plural R¹²'s may be the same as or different from each other.

6. The photosensitive planographic printing plate precursor according to claim 5, wherein the monovalent organic group represented by R¹² is selected from the group consisting of an alkyl group having 1 to 8 carbon atoms, an aryl group having 6 to 10 carbon atoms, a hydroxyl group, and a SO₂NH₂ group.

7. The photosensitive planographic printing plate precursor according to claim 1, wherein the zwitterionic structure is a sulfobetaine structure, a carboxybetaine structure, or a phosphobetaine structure.

8. The photosensitive planographic printing plate precursor according to claim 1, wherein the (A) infrared absorber is a cyanine dye.

9. The photosensitive planographic printing plate precursor according to claim 1, wherein the (B) copolymer further comprises a repeating unit having an alkali-soluble group.

10. The photosensitive planographic printing plate precursor according to claim 1, wherein the image recording layer further comprises an alkali-soluble resin that is different from the (B) copolymer.

11. The photosensitive planographic printing plate precursor according to claim 10, which is a positive-working photosensitive planographic printing plate precursor.

12. The photosensitive planographic printing plate precursor according to claim 1, wherein the image recording layer further comprises a polymerizable compound and a polymerization initiator, and the photosensitive planographic printing plate precursor is a negative-working photosensitive planographic printing plate precursor.

13. A method of producing a planographic printing plate, comprising:
subjecting the photosensitive planographic printing plate precursor of claim 1 to imagewise light exposure; and
developing the photosensitive planographic printing plate precursor after the imagewise light exposure.
